(19) United States
(12) Patent Application Publication
(10) Pub. No.: US 2014/0084957 A1
(43) Pub. Date: Mar. 27, 2014

(54) WIRING CHECK DEVICE AND WIRING CHECK SYSTEM

(71) Applicant: Ken Morishita, Tokyo (JP)

(72) Inventor: Ken Morishita, Tokyo (JP)

(73) Assignee: NEC CORPORATION, Minato-ku, Tokyo (JP)

(21) Appl. No.: 14/119,810

(22) PCT Filed: May 21, 2012
(86) PCT No.: PCT/JP2012/063570

§ 371 Date: Nov. 22, 2013

(30) Foreign Application Priority Data
May 24, 2011 (JP) 2011-116002

(51) Int. Cl. G01R 31/00; G01R 31/28

(52) U.S. Cl. CPC G01R 31/002; G01R 31/2801
USPC 324/763.01

(57) ABSTRACT

An objective of the present invention is to provide a wiring check device with which it is possible, with respect to finding a risk of deterioration of electromagnetic noise characteristics, to take into account the presence of a plane conductor other than a plane conductor located closest to the wiring. A wiring check device according to the present invention includes: a wiring information acquisition unit which acquires wiring information on a wiring which is included in a printed substrate having a multi-layered structure; a plane conductor detection unit which detects a plurality of plane conductors on multiple layers among the multi-layered structure which include a layer located closest to the wiring; a plane conductor overlap configuration detection unit which detects a plane conductor overlap configuration of a configuration in which the plurality of plane conductors overlap; and a bridge point detection unit which detects a point where the wiring steps over a plane conductor excluded region in the plane conductor overlap configuration on the basis of a wiring-plane conductor overlap configuration of a configuration in which the wiring and the plane conductor overlap configuration are overlapped.

### TECHNICAL FIELD

The present invention relates to a wiring check device and a wiring check system of a printed wiring board.

### BACKGROUND ART

In a printed wiring board on which an LSI (Large Scale Integration) and an IC (Integrated Circuit) are mounted, it is necessary to improve an electromagnetic noise characteristic. That is, it is necessary to suppress emission of an unnecessary electromagnetic noise to outside and to prevent destruction and malfunction by electromagnetic noise mixed from outside.

When a design change or an addition of a measure part for improving an electromagnetic noise characteristic is performed after production of a printed wiring board, it will lead to a prolongation of a development period, or increase of a manufacturing cost thereof. Therefore, it is desirable to check an electromagnetic noise characteristic and to take a measure for improving an electromagnetic noise characteristic if needed in a design phase of a printed wiring board.

When a plane conductor which opposes a wiring is missing, and the wiring steps over this missing part, it is known to become a factor which causes deterioration of an electromagnetic noise characteristic of a printed wiring board.

Here, there are a large number of clearance holes formed in order to avoid conducting with vias exist in a plane conductor which becomes a power or a ground of a printed wiring board. Moreover, there are many points where a plane conductor is missing, such as a gap for dividing a power or a ground, and a notch provided in order to let a wiring pass, exist in various shapes. Below, a point where a plane conductor is missing, such as a gap for dividing a power or a ground, and a notch provided in order to let a wiring pass, is called a slit.

When the slit and a wiring oppose, a part where a wiring steps over the slit will be formed. FIG. 1 is a diagram of a state viewed from a substrate top face in which a wiring 1003 which performs input and output for an LSI 1002 steps over a slit 1001 which lies in a lower layer thereof.

When the wiring 1003 steps over the slit 1001, a return path of a signal current becomes longer, and strong electromagnetic noise will be emitted. It becomes easy for electromagnetic noise mixed from outside to superpose on the wiring 1003 around the slit 1001 of a plane conductor 1000, which causes destruction or malfunction of an electronic apparatus.

A technology to check such wiring is disclosed in patent literature 1, for example.

A check device disclosed in the patent literature 1 extracts a wiring which is susceptible to noise and steps over a specified region to a substrate for which a layout design is performed. And interference noise is checked for this wiring. This device includes a region designation means, a wiring extracting means and an interference check means. The region designation means is a means which specifies an optional region to a substrate by which a layout design is performed. The wiring extracting means is a means which extracts a wiring which steps over a region specified by the region designation means and other part. The interference check means is a means which performs a noise interference check to a wiring extracted by the wiring extracting means. According to this device, because an area is specified in accordance with a plane shape of the substrate, it is said that the region designation can be performed automatically even if a user does not perform the region designation separately.

However, in the device described in the patent literature 1, there is a case in which a user performs a region designation for extracting a wiring. Therefore, full automation of a check cannot be performed, and there is a problem that the user has to intervene in a check stage. Although it is described that the region designation can be performed automatically by this device, the automatic region designation has the large restrictions as found from the description of specification paragraph [0021] of patent literature 1. That is, there are restrictions that all layers of the multi-layer printed wiring board must be almost same plane-shaped, and it is effective if there is a wiring only in a plane layer designed by a specific shape.

For example, a technology in relation to a full automation of a check is disclosed in patent literature 2. In a return path cutoff check system of a printed wiring board described in the patent literature 2, it is detected whether a wiring on the printed wiring board is formed only on a single plane layer. In this system, a wiring and plane layers are automatically selected from CAD (Computer Aided Design) data, and the wiring and the plane layers which exist above and below the wiring are overlapped as an image. And it is detected whether the wiring is formed only on the single plane layer.

In the system described in patent literature 2, there is little problem such as a user having to intervene in the check stage, or the restriction in the automatic region designation. However, only information whether a wiring is formed only on the single plane layer is detected by this system. Therefore, it is impossible to defect a magnitude of influence by a wiring formed on a plurality of plane layers in consideration of a difference in a configuration of the wiring or the plane layer.

For example, a technology in relation to a solution of such problem is disclosed in patent literature 3. In patent literature 3, a plane stepping over wiring check system which determines whether a wiring steps over a space between plane layers of a same kind or between different kinds of plane layers is disclosed. In this system, a wiring and a plurality of plane layers of check targets are extracted from CAD data, those projection overlaps are detected, and an attribute of each plane layer is determined. And a wiring which steps over a space between the plane layers of a same kind and a wiring which steps over a space between the plane layers of a different kind are distinguished, and weighting is applied to each wiring. Thereby, level classification by the kind of the plane layer is performed of the degree of influence by the wiring stepping over a space between the plane layers.

### PRIOR ART LITERATURE

### Patent Literature

Patent literature 1: Japanese Patent Application Laid-Open No. 2006-172370
Patent literature 2: Japanese Patent Publication No. 3251263
Patent literature 3: Japanese Patent Application Laid-Open No. 2009-211405

### SUMMARY OF INVENTION

### Problem to be Solved by the Invention

In order to improve an electromagnetic noise characteristic of a printed wiring board, it is effective and efficient to perform a measure design with priority from a wiring with a high risk of deterioration of an electromagnetic noise characteristic.

Here, in the wiring check system described in patent literature 3, a bridge wiring is detected from only a relation between the position of the wiring and the configuration of the plane conductor located just close to the wiring. That is, when a risk of deterioration of an electromagnetic noise characteristic is determined, a plane conductor other than the plane conductor located just close to the wiring is not considered at all.

On the other hand, the inventors of the present application have found that the difference in an electromagnetic noise characteristic occurs depending on the configuration of a plane conductor other than the plane conductor located just close to the wiring. An evaluation result of a relation between a configuration of a plane conductor other than the plane conductor located just proximally to the wiring and an electromagnetic noise characteristic will be described using FIGS. 2 to 5.

Schematic diagrams of printed wiring boards 10 and 20 used for evaluation are shown in FIG. 2 and FIG. 3. FIG. 2A is a diagram viewing the printed wiring board 10 from a top face thereof. FIG. 2B is a sectional view of the printed wiring board 10 along the I-I line. FIG. 3A is a diagram viewing the printed wiring board 20 from a top face thereof. FIG. 3B is a sectional view of the printed wiring board 20 along the II-II line. Further, the printed wiring board 10 and the printed wiring board 20 have the same structure except for the configuration of the plane conductors 12 and 21 formed in the layer C.

The printed wiring boards 10 and 20 are four-layered configurations in which a glass epoxy board (standard notation: FR-4) of a dielectric substrate is used as a substrate material, respectively. A wiring 13 of a line width 0.3 mm and a pad 14 for noise impression are formed respectively in the top layer A. A plane conductor 11 is formed respectively in the layer B of the second layer. A plane conductor 12 is formed in the layer C of the printed wiring board 10 and a plane conductor 21 is formed in the layer C of the printed wiring board 20. A conductive pattern is not formed in the layer D of the fourth layer.

A coaxial connector (SMA connector 15) for voltage measurement is connected to the wiring end of one side of the wiring 13 formed in the layer A, and the other end is open without anything being connected to other wiring end thereof. Moreover, an internal conductor of the SMA connector 15 is connected to the wiring 13 on the layer A, and an outer conductor thereof is connected to the plane conductor 11 on the layer B. The pad 14 is formed in the size of 5 mm square on a substrate end portion and connected by a via with the plane conductor 11 on the layer B. Further, there is no electric connection by a via or a capacitor between the plane conductors on the layer B and the layer C.

A slit with a size of 30 mm×1 mm is formed in the plane conductor 11 on the layer B of respective printed wiring boards 10 and 20 in a position just under the wiring 13 on the layer A. That is, the wiring 13 on the layer A is a wiring which steps over a center of the slit formed in the plane conductor 11 on the layer B. A slit with a size of 30 mm×1 mm is formed in the plane conductor 12 on the layer C of the printed wiring board 10 in a position just under the wiring 13 on the layer A. On the other hand, a slit is not formed in the plane conductor 21 on the layer C of the printed wiring board 20.

Measurement results of an induced voltage to the wiring 13 are shown in FIG. 4 when impressing noise from the pad 14 on the layer A in the printed wiring boards 10 and 20. In those measurements, it is shown that they are susceptible to electromagnetic noise from outside an induced voltage is higher. That is, it is shown that a risk of deterioration of an electromagnetic noise characteristic is higher as an induced voltage is higher.

FIG. 4A shows a measurement result of an induced voltage in a printed wiring board in which a slit is not formed in any of the plane conductors. Below, a printed wiring board in which a slit is not formed in any of the plane conductors is called a standard printed wiring board. FIG. 4B shows a measurement result of an induced voltage generated in the printed wiring board 10 shown in FIG. 2. FIG. 4C shows a measurement result of an induced voltage generated in the printed wiring board 20 shown in FIG. 3.

From FIG. 4, it is found that the induced voltage by the electromagnetic noise impression is large when there is a slit in the plane conductor 11 on the layer B (FIG. 4B and FIG. 4C), compared with the case where there are no slits in both plane conductors (FIG. 4A). Moreover, it is found that an induced voltage by electromagnetic noise impression becomes larger in particular when there is also a slit in the plane conductor 12 on the layer C (FIG. 4B), compared with the case where there are no slits in the plane conductor 21 on the layer C (FIG. 4C), and an electromagnetic noise characteristic of an electronic apparatus deteriorates.

The inventors of the present application also have evaluated a case where slits of plane conductors 31 and 32 as shown in FIG. 5 and FIG. 6 are the substrate end slits.

FIG. 5 shows a printed wiring board 30 in which the slit of the printed wiring board 10 shown in FIG. 2 is made a substrate end slit with the size of 30 mm×1 mm. FIG. 5A is a diagram viewing the printed wiring board 30 from a top face thereof. FIG. 5B is a sectional view of the printed wiring board 30 along the III-III line. The printed wiring board 30 is a four-layered configuration in which a glass epoxy board (standard notation: FR-4) of a dielectric substrate is used as a substrate material. The plane conductors 31 and 32 on the layer B and the layer C have substrate end slits with the size of 30 mm×1 mm. And the wiring 13 steps over the substrate end slit of the plane conductor 31. The substrate end slit represents a slit formed by notching the plane conductor up to the edge of the substrate. FIG. 6 shows a printed wiring board 40 which the slit of the printed wiring board 20 shown in FIG. 3 is made a substrate end slit with the size of 30 mm×1 mm. FIG. 6A is a diagram viewing the printed wiring board 40 from a top face thereof. FIG. 6B is a sectional view of the printed wiring board 40 along the IV-IV line. The printed wiring board 40 is a four-layered configuration in which a glass epoxy board (standard notation: FR-4) of a dielectric substrate is used as a substrate material. The plane conductor 31 on the layer B has a substrate end slit with the size of 30 mm×1 mm. The plane conductor 41 on the layer C does not have a slit. And the wiring 13 steps over the substrate end slit of the plane conductor 31.

Measurement results of induced voltages of the printed wiring boards 30 and 40 shown in FIG. 5 and FIG. 6 are shown in FIG. 7. A Peak-to-Peak value (Vpp) which represents the maximum amplitude of the voltage is shown in FIG. 7 for the evaluation of the induced voltage. FIG. 7 also shows the measurement results of the induced voltage for the standard printed wiring board without a slit in both plane conductors and the printed wiring boards 10 and 20 shown in FIG. 2 and FIG. 3.

From FIG. 7, it is found that the induced voltages differ depending on presence or absence of a slit in the plane conductor on the layer C even though the substrate end slit is formed in the plane conductor on the layer B. That is, the induced voltage of the printed wiring board 10 in which slits are formed in the plane conductors on the layer B and the layer C, respectively is 3.5 times larger than the induced voltage of the standard printed wiring board, and the induced voltage of the printed wiring board 20 in which the slit is formed only in the plane conductor on the layer B is 1.4 times larger than the induced voltage of the standard printed wiring board. The induced voltage of the printed wiring board 30 in which a substrate end slit is formed in the plane conductors on the layer B and the layer C is 6.7 times larger than of the induced voltage of the standard printed wiring board, and the induced voltage of the printed wiring board 40 in which a slit is formed only in the plane conductor on the layer B is 1.7 times larger than the induced voltage of the standard printed wiring board. FIG. 7, if the wiring steps over the substrate end slit as the printed wiring boards 30 and 40, it is found that the induced voltage becomes larger than that in the case where the wiring steps over the slit inside the substrate as the printed wiring boards 10 and 20.

It is found from the above mentioned measurement results that the difference occurs in the electromagnetic noise characteristic depending on the configuration of the plane conductor other than the nearest plane conductor to the wiring even if the configuration of the slit in the nearest plane conductor to the wiring is the same.

That is, if a plurality of plane conductors are overlapped in the substrate laminating direction and the slit in the nearest plane conductor to the wiring is covered with other plane conductors, it is found that the influence on an electromagnetic noise characteristic becomes small.

The principle by which the influence on the electromagnetic noise characteristic becomes small by other plane conductors covering the slit in the plane conductor most close to the wiring will be described using FIG. 8. FIG. 8 shows a noise current which flows through the neighborhood of the slit formed in the plane conductor in the printed wiring board with a multi-layered structure, and an electromagnetic field which occurs by the noise current. A case where there is no other plane conductor in layers above and below the plane conductor 50 having the slit is shown in FIG. 8A. FIG. 8B shows a sectional view of the printed wiring board along the V-V line in FIG. 8A. If a wiring is provided in a position opposing a slit in the plane conductor 50, a noise current is generated as shown in FIG. 8A and FIG. 8B, and an electromagnetic field arises in the neighborhood of the slit. And as shown in FIG. 8B, this electromagnetic field couples with the wiring and induces a voltage.

On the other hand, FIG. 8C shows a case where there is a plane conductor 52 without a slit in a lower layer of the plane conductor 51 having a slit. A sectional view along the VI-VI line of the printed wiring board in FIG. 8C is shown in FIG. 8D. If a wiring is provided in a position opposing a slit in the plane conductor 51, a noise current is generated as the case in FIG. 8A and FIG. 8B, and an electromagnetic field occurs in the neighborhood of the slit. Here, if there is the plane conductor 52, as shown in FIG. 8D, an electromagnetic field generated by a noise current which flows through the slit periphery of the plane conductor 51 generates an eddy current on the surface of the plane conductor 52. This eddy current generates an electromagnetic field in a direction opposite to the electromagnetic field produced by the noise current of the plane conductor 51. And the magnetic field by the noise current of the plane conductor 51 is canceled by the electromagnetic field produced by this eddy current, and an electromagnetic field around the slit is weakened. Thereby, even if the wiring is provided in the upper side of the plane conductor 51 or in the position opposite to the slit of the plane conductor 51 between the plane conductor 51 and the plane conductor 52, a voltage induced in the wiring becomes small. That is, a risk of deterioration of an electromagnetic noise characteristic is reduced by the other plane conductor 52 located immediately above or below the slit of the plane conductor 51.

In FIGS. 8C and 8D, an electromagnetic field produced by the noise current in the plane conductor 51 couples with the plane conductor 52 strongly as the distance between the plane conductor 51 and the plane conductor 52 is closer. Thereby, an eddy current which occurs in the plane conductor 52 also becomes larger. Therefore, the effect that cancels an electromagnetic field by the noise current in the plane conductor 51 becomes higher. That is, a risk of deterioration of an electromagnetic noise characteristic is reduced as the distance between the plane conductor 51 and the plane conductor 52 is closer.

It is found that the risks of deterioration of an electromagnetic noise characteristic differs due to the presence of plane conductors other than the plane conductor located closest to the wiring, based on the above mentioned principle.

As mentioned above, in order to improve an electromagnetic noise characteristic of a printed wiring board, it is effective and efficient to perform preferentially a measure design of a wiring with a high risk of deteriorating of an electromagnetic noise characteristic. Therefore, in a system to check a wiring, it is desirable to take into account the presence of a plane conductor other than the plane conductor located closest to the wiring.

On the other hand, as mentioned above, in the wiring check system disclosed in patent literature 3, a bridge wiring is detected only by the relation between the position of the wiring and the configuration of the plane conductor located closest to the wiring. That is, the effect is not taken into account at all that a risk of deterioration of an electromagnetic noise characteristic is reduced by the presence of a plane conductor other than the plane conductor located closest to the wiring, Therefore, an electromagnetic noise characteristic cannot be improved efficiently.

The objective of the present invention is to provide a wiring check device, a wiring check system, a wiring check method, a wiring check program, and a recording medium where it is possible, with respect to finding a risk of deterioration of electromagnetic noise characteristics, to take into account the presence of a plane conductor other than a plane conductor which is located closest to the wiring.

### Means for Solving the Problem

In order to achieve the above object, a wiring check device according to this exemplary embodiment comprising: a wiring information acquisition unit which acquires wiring information on a wiring comprised in a printed wiring board having a multi-layered structure; a plane conductor detection unit which detects a plurality of plane conductors on multiple layers among the multi-layered structure comprising a layer located closest to a layer comprising the wiring; a plane conductor overlap configuration detection unit which detects a plane conductor overlap configuration of a configuration in which the plurality of plane conductors are overlapped; and a bridge point detection unit which detects a point where the wiring steps over a plane conductor excluded region in the plane conductor overlap configuration on the basis of a wiring-plane conductor overlap configuration of a configuration in which the wiring and the plane conductor overlap configuration are overlapped.

A wiring check system according to this exemplary embodiment comprising: a wiring information acquisition means which acquires wiring information on a wiring comprised in a printed wiring board having a multi-layered structure; a plane conductor detection means which detects a plurality of plane conductors on multiple layers among the multi-layered structure which comprise a layer located closest to a layer comprising the wiring; a plane conductor overlap configuration detection means which detects a plane conductor overlap configuration of a configuration in which the plurality of plane conductors are overlapped; and a bridge point detection means which detects a point where the wiring steps over a plane conductor excluded region in the plane conductor overlap configuration on the basis of a wiring-plane conductor overlap configuration of is a configuration in which the wiring and the plane conductor overlap configuration are overlapped.

A wiring checking method according to this exemplary embodiment comprising: a wiring information acquisition step which acquires wiring information on a wiring comprised in a printed wiring board having a multi-layered structure; a plane conductor detection step which detects a plurality of plane conductors on multiple layers among the multi-layered structure comprising a layer located closest to a layer comprising the wiring; a plane conductor overlap configuration detection step which detects a plane conductor overlap configuration of a configuration in which the plurality of plane conductors are overlapped; and a bridge point detection step which detects a point where the wiring steps over a plane conductor excluded region in the plane conductor overlap configuration on the basis of a wiring-plane conductor overlap configuration of a configuration in which the wiring and the plane conductor overlap configuration are overlapped.

A wiring check program according to this exemplary embodiment for making a computer executes steps of: a wiring information acquisition step which acquires wiring information on a wiring comprised in a printed wiring board having a multi-layered structure; a plane conductor detection step which detects a plurality of plane conductors on multiple layers among the multi-layered structure comprising a layer located closest to a layer comprising the wiring; a plane conductor overlap configuration detection step which detects a plane conductor overlap configuration of a configuration in which the plurality of plane conductors are overlapped; and a bridge point detection step which detects a point where the wiring steps over a plane conductor excluded region in the plane conductor overlap configuration on the basis of a wiring-plane conductor overlap configuration of a configuration in which the wiring and the plane conductor overlap configuration are overlapped.

A recording medium according to this exemplary embodiment which is a computer readable storage medium recording a wiring check program according to the present invention

### Effect of the Invention

According to the present invention, it becomes possible, with respect to finding a risk of deterioration of electromagnetic noise characteristics, to take into account the presence of a plane conductor other than a plane conductor which is located closest to the wiring.

### BRIEF DESCRIPTION OF THE DRAWINGS

FIG. 1 shows an example of a plane conductor in which slits with a plurality of shapes are formed.

FIG. 2A and FIG. 2B show a schematic diagram of a printed wiring board used for verification.

FIG. 3A and FIG. 3B show a schematic diagram of a printed wiring board used for verification.

FIGS. 4A to 4C show measurement results of an induced voltage.

FIG. 5A and FIG. 5B show a schematic diagram of a printed wiring board used for verification.

FIG. 6A and FIG. 6B show a schematic diagram of a printed wiring board used for verification.

FIG. 7 shows a measurement result of an induced voltage.

FIGS. 8A to 8D show the effect by the existence of a plane conductor other than the nearest plane conductor to a wiring.

FIG. 9 shows an example of a configuration of a wiring check system in a first exemplary embodiment of the present invention.

FIG. 10 shows an example of operation of the wiring check system in the first exemplary embodiment of the present invention.

FIGS. 11A to 11C show a schematic diagram of a target printed wiring board on a wiring check by the wiring check system in the first exemplary embodiment of the present invention.

FIG. 12A and FIG. 12B show an overlap configuration which the wiring check system in the first exemplary embodiment of the present invention detected.

FIG. 13 shows an example of a configuration of a wiring check system in a second exemplary embodiment of the present invention.

FIG. 14 shows an example of operation of the wiring check system in the second exemplary embodiment of the present invention.

FIGS. 15A to 15C show a diagram illustrating an example of a wiring checking method by the wiring check system in the second exemplary embodiment of the present invention.

FIGS. 16A to 16C show a diagram illustrating an example of a wiring checking method in a third exemplary embodiment of the present invention.

FIG. 17A and FIG. 17B show a diagram illustrating the wiring checking method in the third exemplary embodiment of the present invention.

FIG. 18A and FIG. 18B show a diagram illustrating other example of the wiring checking method in the third exemplary embodiment of the present invention.

FIG. 19 shows other example of a configuration of a wiring check system in the third exemplary embodiment of the present invention.

FIG. 20 shows a measurement result about a relation between the size of the slit and the induced voltage.

FIG. 21 shows an example of a configuration of a wiring check system in a fourth exemplary embodiment of the present invention.

FIG. 22 shows other example of a configuration of the wiring check system in the fourth exemplary embodiment of the present invention.

FIG. 23 shows an example of operation of the wiring check system in the fourth exemplary embodiment of the present invention.

FIG. 24A and FIG. 24B show a diagram illustrating a wiring checking method in the fourth exemplary embodiment of the present invention.

FIG. 25A and FIG. 25B show a simulation model for verifying the difference in the induced voltages by presence or absence in a joint.

FIG. 26 shows a pulse waveform of a voltage inputted to a voltage source.

FIG. 27 shows a result of simulation for verifying the difference in the induced voltages by presence or absence in a joint.

FIG. 28A and FIG. 28B show a simulation model for verifying the difference in the induced voltages by presence or absence in a joint.

FIG. 29 shows a result of simulation for verifying the difference in the induced voltages by presence or absence in a joint.

FIG. 30A and FIG. 30B show a diagram for explaining the range of the joint.

FIG. 31 shows an example of a configuration of a wiring check system in a fifth exemplary embodiment of the present invention.

FIG. 32 shows an example of operation of the wiring check system in the fifth exemplary embodiment of the present invention.

FIG. 33A and FIG. 33B show a diagram illustrating a wiring checking method in the fifth exemplary embodiment of the present invention.

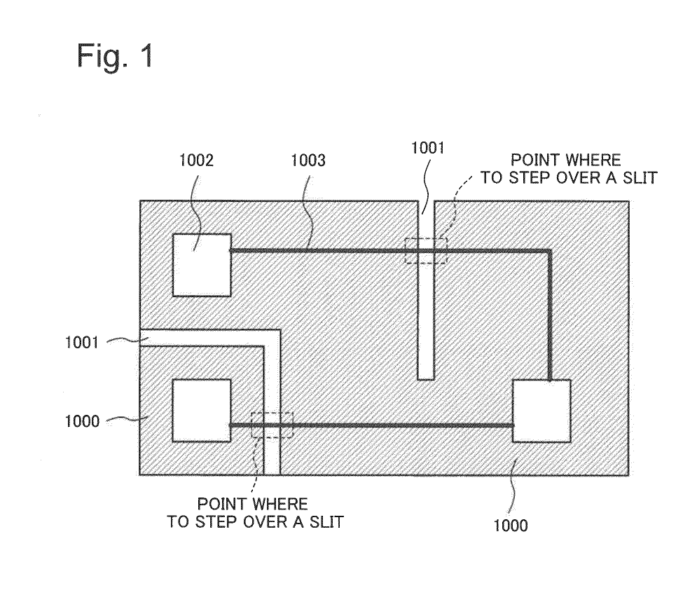

### DESCRIPTION OF EMBODIMENTS

Exemplary embodiments of the present invention will be described with reference to drawings. However, the exemplary embodiments do not limit the technical scope of the present invention.

### First Exemplary Embodiment

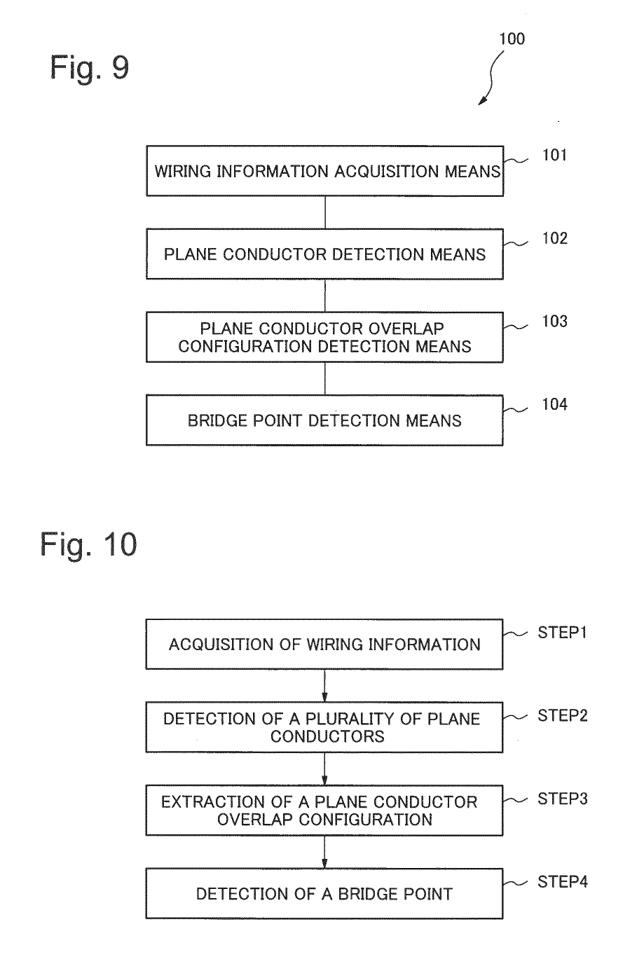

A wiring check system according to a first exemplary embodiment of the present invention will be described using FIG. 9.

A wiring check system 100 according to this exemplary embodiment includes a wiring information acquisition means 101, a plane conductor detection means 102, a plane conductor overlap configuration detection means 103 and a bridge point detection means 104.

The wiring information acquisition means 101 acquires wiring information on a wiring included in a printed wiring board having a multi-layered structure. The plane conductor detection means 102 detects a plurality of plane conductors of multiple layers including a layer nearest to a layer having a wiring among the multi-layered structure. The plane conductor overlap configuration detection means 103 detects a plane conductor overlap configuration which is a configuration in which a plurality of plane conductors are overlapped. The bridge point detection means 104 detects a wiring-plane conductor overlap configuration which is a configuration of overlapping a wiring and a plane conductor overlap configuration. And a point where a wiring steps over a plane conductor excluded region in the plane conductor overlap configuration is detected based on the wiring-plane conductor overlap configuration.

Next, a wiring checking method of a printed wiring board by the wiring check system 100 in this exemplary embodiment will be described using FIG. 10.

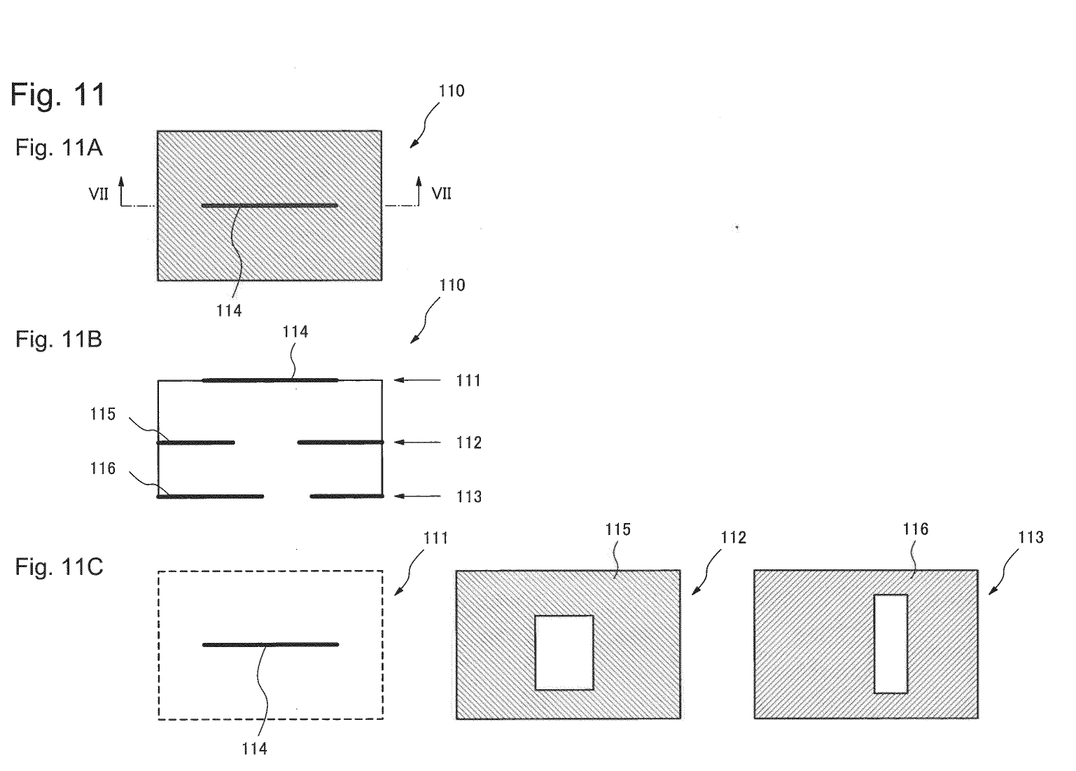

A printed wiring board for which a wiring check is performed by the wiring check system 100, a printed wiring board 110 shown in FIG. 11 will be used. The printed wiring board 110 has a multi-layered structure including the three-layered structure. The respective layers are represented by a layer 111, a layer 112 and a layer 113 from the top layer shown in FIG. 11. The layer 111 has a wiring 114. The layer 112 has a plane conductor 115. The layer 113 has a plane conductor 116. FIG. 11A shows a top view of the printed wiring board 110. FIG. 11B shows a sectional view along the VII-VII line of the printed wiring board 110. FIG. 11C shows a top view of respective layers 111-113 of the printed wiring board 110.

First, the wiring information acquisition means 101 acquires wiring information on the wiring 114 (Step 1). The wiring 114 here is a target wiring checked by the wiring check system 100.

Next, the plane conductor detection means 102 detects a plurality of plane conductors 115 and 116 in the multiple layers 112 and 113 including the layer 112 nearest to the layer 111 having the wiring 114 (Step 2).

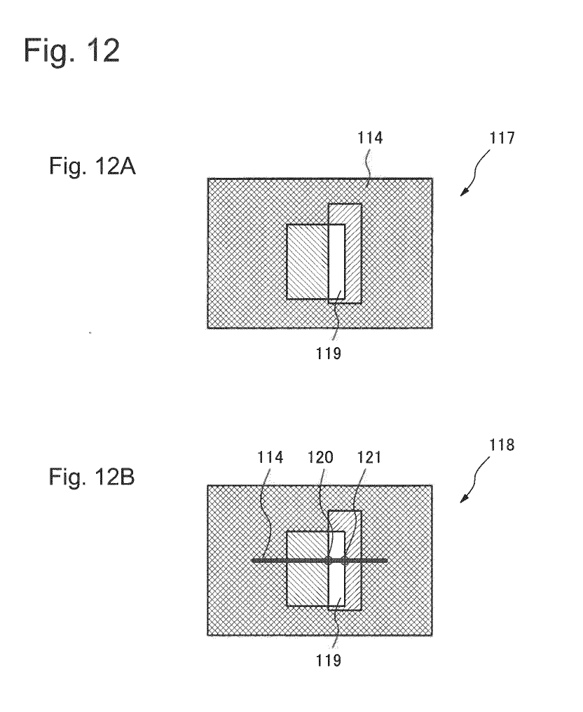

And the plane conductor overlap configuration detection means 103 detects the configuration in which the plane conductors 115 and 116 overlap with each other (Step 3). Below, the configuration in which the plane conductors 115 and 116 overlap with each one another will be called a plane conductor overlap configuration 117. The plane conductor overlap configuration 117 is shown in FIG. 12.

The bridge point detection means 104 detects bridge points 120 and 121 which are points in which the wiring 114 steps over the plane conductor excluded region 119 in the plane conductor overlap configuration 117 from a configuration in which the wiring and the plane conductor overlap configuration are overlapped (Step 4). Below, the configuration in which this wiring and the plane conductor overlap configuration are overlapped will be called a wiring-plane conductor overlap configuration 118.

The wiring check system is completed as mentioned above. Although a wiring provided in the printed wiring board 110 is only the wiring 114, if a wiring check of the printed wiring board having a plurality of wirings is performed, steps 1-4 are performed for the respective wirings.

As mentioned above, according to the wiring check system 100 of this exemplary embodiment, it is possible, with respect to finding a risk of deterioration of electromagnetic noise characteristics, to take into account the configuration of a plane conductor other than the plane conductor which is located closest to the wiring.

Therefore, an electromagnetic noise characteristic of a printed wiring board can be improved efficiently.

Further, the wiring check system 100 according to this exemplary embodiment may be configured by a single device, or may be configured by a plurality of devices.

### Second Exemplary Embodiment

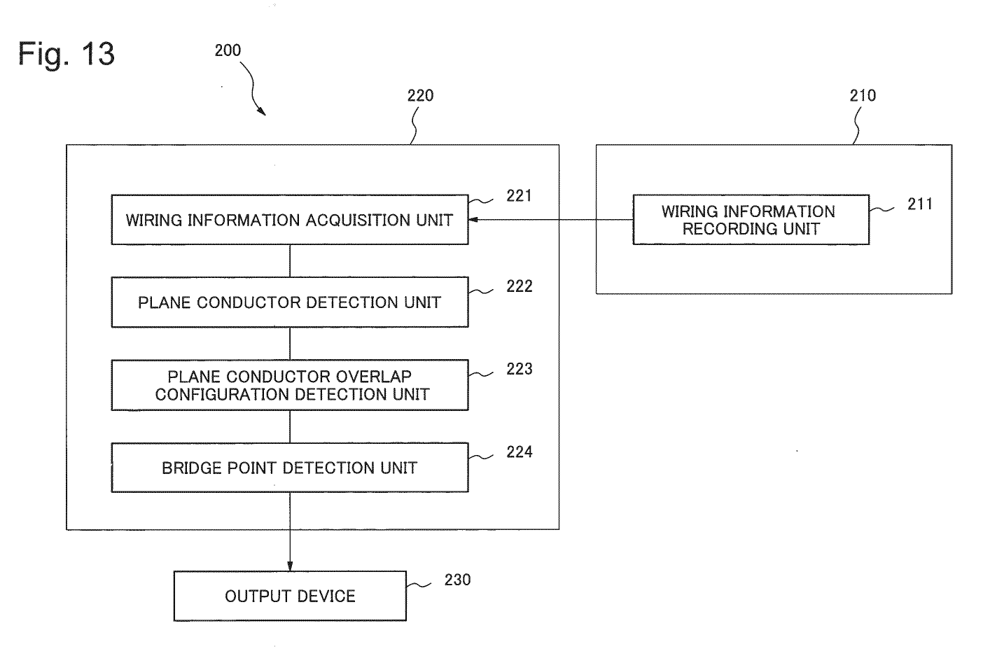

A wiring check system according to a second exemplary embodiment of the present invention will be described using FIG. 13. A wiring check system 200 according to this exemplary embodiment includes a recording device 210, a wiring check device 220 and an output device 230. The wiring check device 220 is in the state which can communicate with each of the recording device 210 and the output device 230 by a wire or a wireless.

The recording device 210 includes a design information recording unit 211. The design information recording unit 211 records design information (CAD data) on a printed wiring board. For example, position information on a wiring of a printed wiring board is included in the design information.

The wiring check device 220 includes a wiring information acquisition unit 221, a plane conductor detection unit 222, a plane conductor overlap configuration detection unit 223 and a bridge point detection unit 224.

The wiring information acquisition unit 221 refers to the design information recorded in the design information recording unit 211 and acquires wiring information on a wiring which becomes a check target. The plane conductor detection unit 222 detects a plurality of plane conductors of multiple layers including a layer nearest to the layer of the wiring. The plane conductor overlap configuration detection unit 223 detects a plane conductor overlap configuration which is a configuration in which a plurality of plane conductors which the plane conductor detection unit 222 detected overlap one another. The bridge point detection unit 224 detects a wiring-plane conductor overlap configuration which is a configuration in which a wiring which becomes a check target and a plane conductor overlap configuration are overlapped. And the bridge point detection unit 224 detects a bridge point which the wiring steps over a plane conductor excluded region in the plane conductor overlap configuration on the basis of a wiring-plane conductor overlap configuration.

The output device 230 outputs information on the bridge point detected by the bridge point detection unit 224.

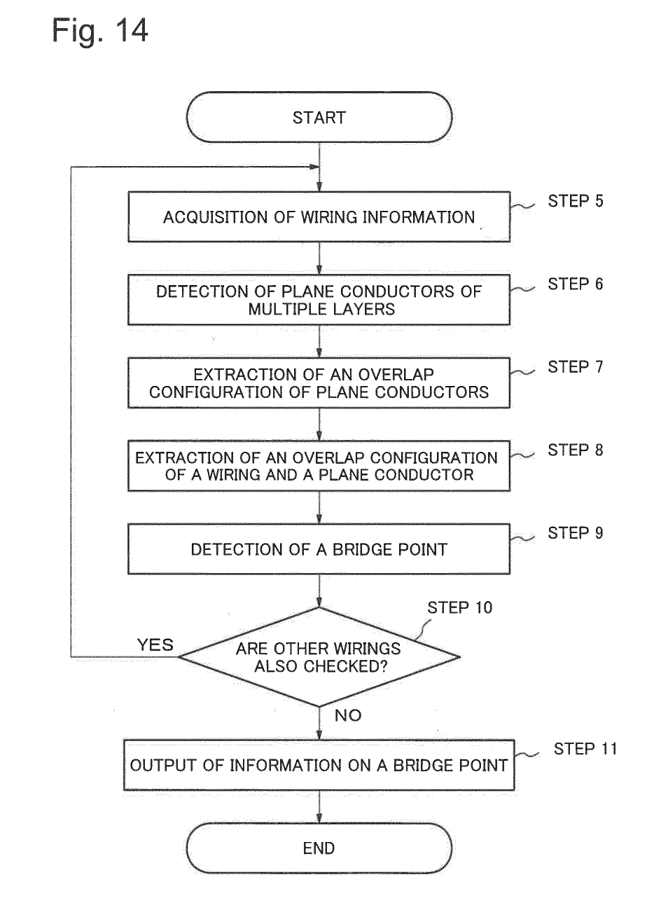

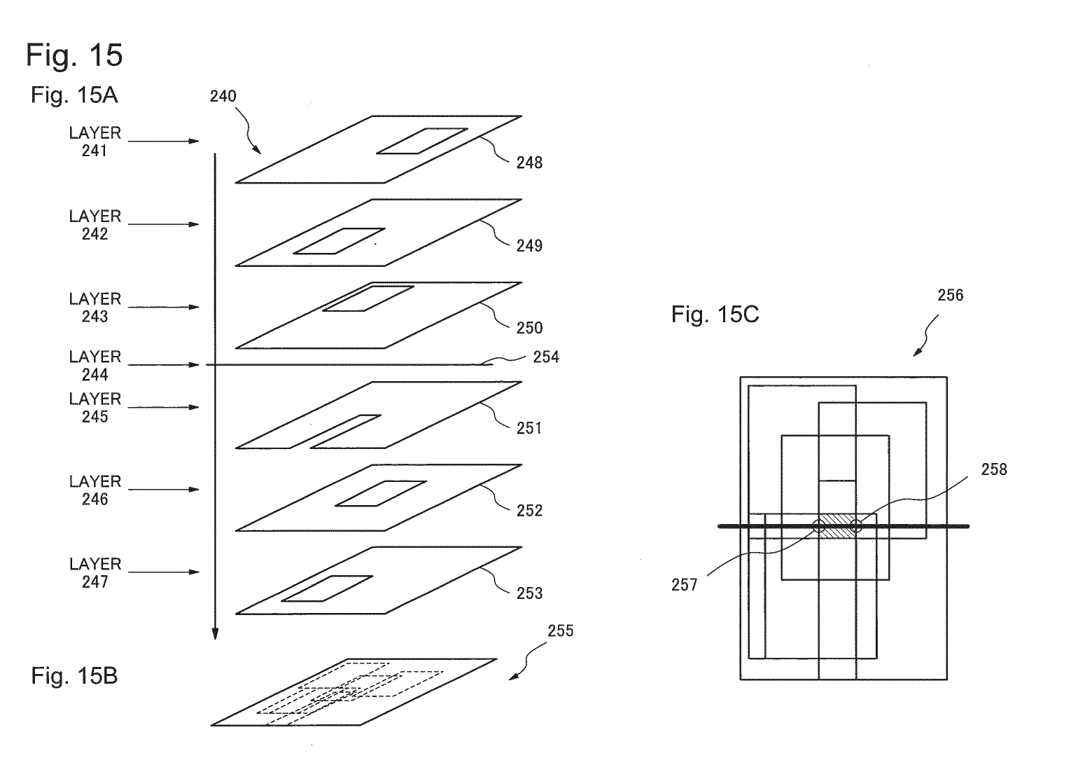

Next, a wiring checking method of a printed wiring board by the wiring check system 200 of this exemplary embodiment will be described using a flow chart shown in FIG. 14. Further, as a printed wiring board performed a wiring check by the wiring check system 200, a printed wiring board 240 shown in FIG. 15A will be used. The printed wiring board 240 has seven layered structure of layers 241-247. The layers 241-243 and the layers 245-247 have plane conductors 248-253. The layer 244 has a wiring 254. Further, it is assumed that the design information on the printed wiring board 240 is recorded in the design information recording unit 211 in advance.

When the wiring check system 200 begins to operate, the wiring information acquisition unit 221 reads a CAD data of the printed wiring board 240 recorded in the design information recording unit 211. And the wiring information acquisition unit 221 acquires wiring information on the wiring 254 which becomes a check target (Step 5). For example, wiring information is a position coordinate (such as XY coordinates) of a wiring or information on a wiring layer.

Next, the plane conductor detection unit 222 detects the plane conductors 248-253 provided in the multiple layers (layers 241-247) including the layers 243 and 245 nearest to the layer 244 having the wiring 254 based on the acquired wiring information (Step 6). At that time, the plane conductor detection unit 222 detects the plane conductors by reading the CAD data of the printed wiring board 240 recorded in the design information recording unit 211.

Next, the plane conductor overlap configuration detection unit 223 detects a plane conductor overlap configuration 255 which is a configuration in which the plane conductors 248-253 which the plane conductor detection unit 222 detected overlap (Step 7). FIG. 15B shows a perspective view of the plane conductor overlap configuration 255.

And the bridge point detection unit 224 detects a wiring-plane conductor overlap configuration 256 which is a configuration in which the plane conductor overlap configuration 255 and the wiring 254 have overlapped one another (Step 8). FIG. 15C shows a top view of the wiring-plane conductor overlap configuration 256.

And the bridge point detection unit 224 detects a point where the wiring 254 steps over a plane conductor excluded region in the plane conductor overlap configuration 255 from the wiring-plane conductor overlap configuration 256 (Step 9). That is, the bridge point which the bridge point detection unit 224 detects is a point in which the wiring 254 steps over a region where neither plane conductors of the plane conductors 248-253 are formed. In this exemplary embodiment, the bridge point detection unit 224 detects bridge points 257 and 258 shown in FIG. 15C.

When there is a target wiring of a wiring check in addition to the wiring 254 (in Step 10, YES), the wiring information acquisition unit 221 reads the design information again and repeats the steps from Step 5 to Step 9. On the other hand, when there are no target wirings on a wiring check (in Step 10, NO), information on the bridge point which the bridge point detection unit 224 detected is transmitted to the output device 230. And the output device 230 outputs information on the received bridge point (Step 11). Here, the output device 230 may display information on the received bridge point on a display screen and may print. Thus, the wiring check by the wiring check system 200 ends.

In the way mentioned above, the wiring check system 200 in this exemplary embodiment detects a bridge point, taking into account not only the plane conductors 243 and 245 which are located closest to the wiring 254, but also the configurations of the plane conductors 241, 242, 246 and 247.

Therefore, it is possible, with respect to finding a risk of deterioration of electromagnetic noise characteristics, to take into account the presence of a plane conductor other than the plane conductor which is located closest to the wiring. That is, it is possible to know a risk of a deterioration of electromagnetic noise characteristics by the presence of a plane conductor other than the plane conductor which is located closest to the wiring, taking into account the effect of reducing the risk of a deterioration of electromagnetic noise characteristics. Therefore, an electromagnetic noise characteristic of a printed wiring board can be improved efficiently.

Further, according to this exemplary embodiment, the plane conductors of all layers provided in the printed wiring board are detected and overlapped. That is, all the plane conductors overlap one another irrespective of in what layer the wiring exists. Therefore, even when many wirings which become check targets are arranged in a plurality of layers, all plane conductors should always be detected, and one configuration in which all plane conductors overlap one another should also be detected about the overlap thereof. Therefore, operation of the plane conductor detection unit 222 and the plane conductor overlap configuration detection unit 223 can be set as the same operation irrespective of the position of the wiring, respectively.

Here, in some printed wiring board, a plane conductor is often arranged in the same layer as a wiring. That is, a wiring and a plane conductor are often intermingled in one layer. However, in a layer where a wiring exists, a plane conductor does not exist in a position in which the wiring exists. Therefore, even if a plane conductor in the same layer as the wiring is included, or not included, a position of a point where the wring steps over a plane conductor excluded region in the configuration in which a plurality of plane conductors overlap one another does not change. Therefore, the plane conductor detection unit 222 does not need to detect the plane conductor of the same layer as the wiring.

However, as shown in a fourth exemplary embodiment mentioned later, when detecting a bridge point and taking into account an area of a plane conductor excluded region, a detected bridge point may be different by whether the plane conductor of the same layer as the wiring is included or not.

Further, the bridge point includes a point where a wiring steps over a plane conductor excluded region formed inside the plane conductor, and a point where the wiring step over a plane conductor excluded region formed between a plurality of plane conductors. A point where a wiring steps over a plane conductor excluded region formed inside the plane conductor will be called an in-plane conductor bridge point below. A point where a wiring steps over a plane conductor excluded region formed between a plurality of plane conductors an inter-plane conductor bridge point below. Therefore, the bridge point includes an in-plane conductor bridge point and an inter-plane conductor bridge point. Here, the bridge point detection unit 224 may distinguish and detect an in-plane conductor bridge point and inter-plane conductor bridge point. Because an inter-plane conductor bridge point has generally a higher risk of deterioration of an electromagnetic noise characteristic compared with an in-plane conductor bridge point, it is possible to take a design measure more efficiently, and to improve an electromagnetic noise characteristic by distinguishing and detecting them.

### Third Exemplary Embodiment

Next, a third exemplary embodiment of the present invention is described.

In the second exemplary embodiment, as the wiring checking method of the wiring check system 200, the method to overlap all plane conductors 248-253 provided in the printed wiring board 240 is used. Below, the method to overlap all the plane conductors 248-253 provided in this printed wiring board 240 will be called a first wiring checking method. However, the wiring checking method by the wiring check system 200 is not limited to this.

For example, a plurality of detected plane conductors may be distinguished and detected the plane conductors located above the wiring, and the plane conductors located below the wiring, respectively, and they may be overlapped in each group.

Only the plane conductor within a predetermined distance from the wiring may be detected among a plurality of plane conductors provided in the printed wiring board.

Accordingly, according to this exemplary embodiment, such other wiring checking methods by the wiring check system 200 are described.

First, the method in which the plane conductors detected by the plane conductor detection unit 222 are distinguished by the plane conductors located above the wiring and the plane conductors located below the wiring, respectively, and they may be overlapped in each group is described. Below, the method in which the plane conductors located above the wiring and the plane conductors located below the wiring are distinguished, and they are overlapped in each group is called a second wiring checking method.

Further, as a target printed wiring board on a wiring check, the printed wiring board 240 shown in FIG. 15A will be used like the second exemplary embodiment. Because Step 5 is similar to the first wiring checking method in the second exemplary embodiment, the description thereof will be omitted.

The plane conductor detection unit 222 detects the plane conductors 248-250 located above the wiring 254, and the plane conductors 251-253 located below the wiring 254, respectively.

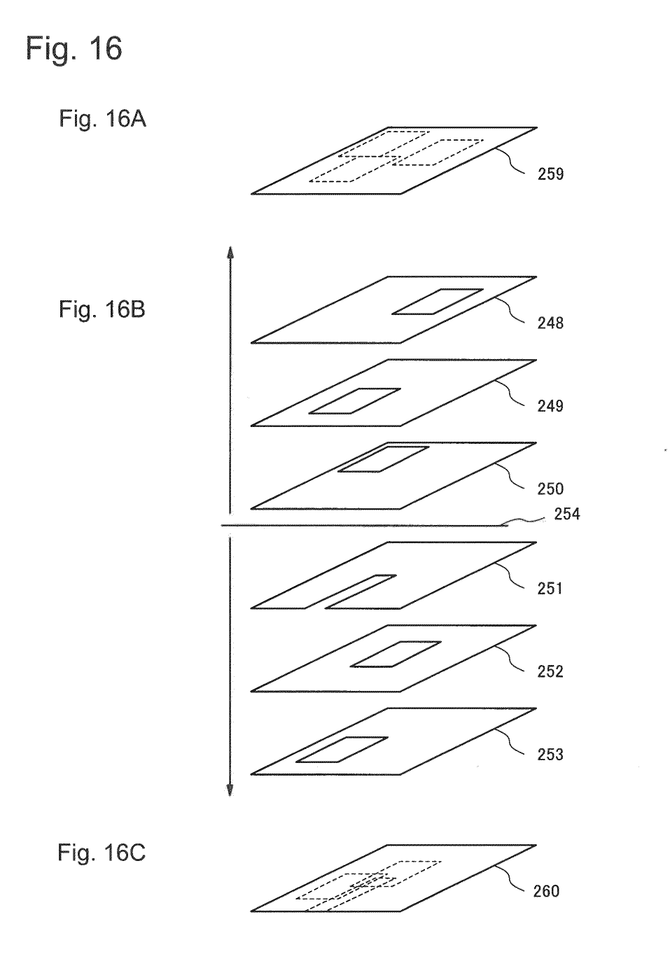

And the plane conductor overlap configuration detection unit 223 detects a configuration in which the plane conductors 248-250 located above the wiring 254 overlap one another. Below, the configuration in which the plane conductors 248-250 located above the wiring 254 overlap one another is called an upper plane conductor overlap configuration 259. Similarly, the plane conductor overlap configuration detection unit 223 also detects a configuration in which the plane conductors 251-253 located below the wiring 254 overlap one another. Below, the configuration in which the plane conductors 251-253 located below the wiring 254 overlap one another is called a lower plane conductor overlap configuration 260. The upper plane conductor overlap configuration 259 and the lower plane conductor overlap configuration 260 are shown in FIG. 16.

Next, the bridge point detection unit 224 detects a configuration in which the wiring 254 and the upper plane conductor overlap configuration 259 overlap one another. Below, the configuration in which the wiring 254 and the upper plane conductor overlap configuration 259 overlap is called a wiring-upper plane conductor overlap configuration. Similarly, the bridge point detection unit 224 also detects a configuration in which the wiring 254 and the lower plane conductor overlap configuration 260 overlap. Below, the configuration in which the wiring 254 and the lower plane conductor overlap configuration 260 overlap one another is called a wiring-lower plane conductor overlap configuration.

And the bridge point detection unit 224 detects a point where the wiring 254 steps over a plane conductor excluded region from each of the wiring-upper plane conductor overlap configuration and the wiring-lower plane conductor overlap configuration. And information on the bridge point detected by the bridge point detection unit 224 is outputted by the output device 230. In the way mentioned above, a wiring check by the second wiring checking method completes.

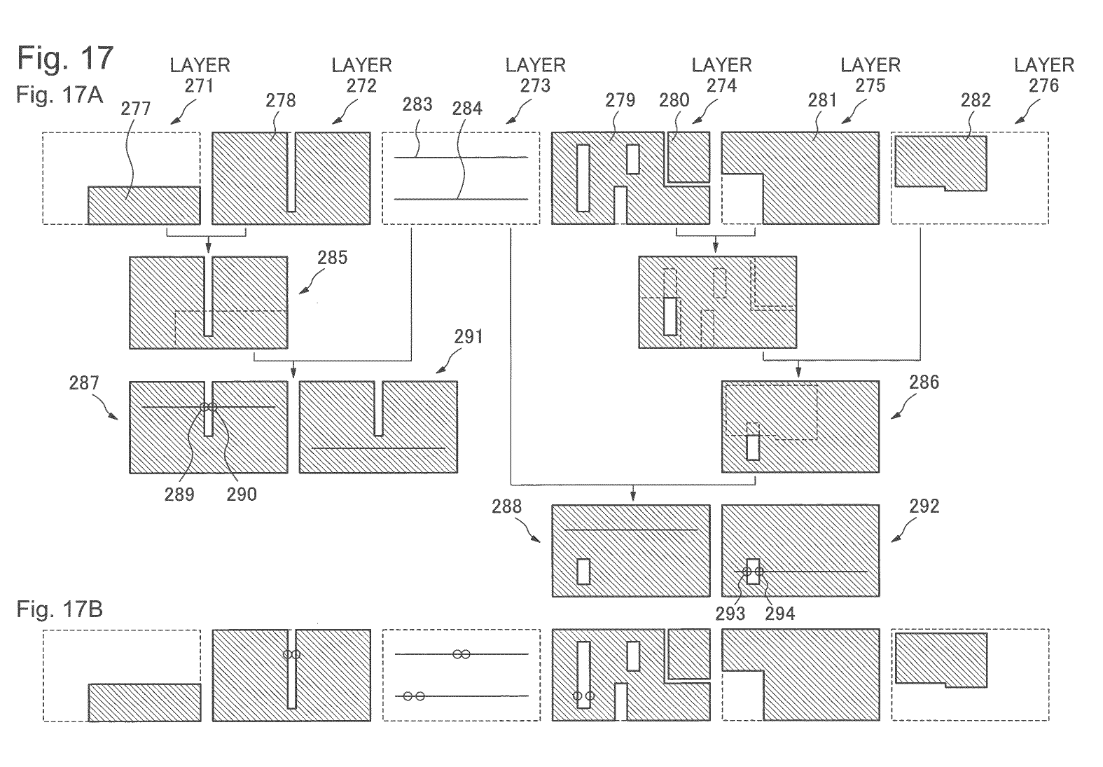

Next, the second wiring checking method is described with a more detailed specific example. Here, a printed wiring board 270 will be used as a target on a wiring check. The printed wiring board 270 has a 6 layered structure of layers 271-276. Further, although not being illustrated, the layers 271-276 are laminated by this order, and the layer 271 is the top layer, and the layer 276 is the bottom layer. A top view of each layer of the printed wiring board 270 is shown in FIG. 17. The layers 271 and 272 and the layers 274-276 have plane conductors 277-282. The layer 273 has wirings 283 and 284. Further, the slant lines part in FIG. 17 shows a plane conductor formation region which is a region where a plane conductor is formed. A dotted line shows a contour of the printed wiring board 270.

First, the wiring information acquisition unit 221 acquires wiring information on the wiring 283 from the design information recording unit 211.

Next, the plane conductor detection unit 222 detects a plurality of plane conductors of multiple layers including the nearest layers 272 and 274 to the layer 273 having the wirings 283. Here, the plane conductor detection unit 222 detects the plane conductors 277 and 278 provided in the layers above the layer 273 having the wirings 283. Similarly, the plane conductor detection unit 222 detects the plane conductors 279-282 provided in the layers below the layer 273 having the wirings 283.

The plane conductor overlap configuration detection unit 223 detects a configuration in which the plane conductors 277 and 278 overlap. Below, the configuration in which the plane conductors 277 and 278 overlap one another is called an upper plane conductor overlap configuration 285. Similarly, the plane conductor overlap configuration detection unit 223 detects a configuration in which the plane conductors 279-282 overlap. Below, the configuration in which the plane conductors 279-282 overlap one another is called a lower plane conductor overlap configuration 286.

Next, the bridge point detection unit 224 detects a configuration in which the wiring 283 and the upper plane conductor overlap configuration 285 overlap one another. Below, the configuration in which the wiring 283 and the upper plane conductor overlap configuration 285 overlap is called a wiring-upper plane conductor overlap configuration 287. Similarly, the bridge point detection unit 224 detects a configuration in which the wiring 283 and the lower plane conductor overlap configuration 286 overlap one another. Below, the configuration in which the wiring 283 and the lower plane conductor overlap configuration 286 overlap one another is called a wiring-lower plane conductor overlap configuration 288.

And the bridge point detection unit 224 detects points (bridge points 289 and 290) where the wiring 283 steps over a plane conductor excluded region in the upper plane conductor overlap configuration 285 based on the wiring-upper plane conductor overlap configuration 287. Similarly, the bridge point detection unit 224 detects a point where the wiring 283 steps over a plane conductor excluded region in the lower plane conductor overlap configuration 286 based on the wiring-lower plane conductor overlap configuration 288. Further, because there is no point in which the wiring 283 steps over a plane conductor excluded region in the wiring-lower plane conductor overlap configuration 288, a bridge point is not detected. In the way mentioned above, the detection of the bridge point in the wiring 283 completes.

Next, the wiring information acquisition unit 221 acquires wiring information on the wiring 284 from the design information recording unit 211. And the wiring-upper plane conductor overlap configuration 291 and the wiring-lower plane conductor overlap configuration 292 are detected by the same step as in case of the wiring 283.

And the bridge point detection unit 224 detects a point where the wiring 284 steps over a plane conductor excluded region in the upper plane conductor overlap configuration 285 based on the wiring-upper plane conductor overlap configuration 291. A bridge point is not detected in the wiring-upper plane conductor overlap configuration 291 because there is not a point where the wiring 284 steps over a plane conductor excluded region. Similarly, the bridge point detection unit 224 detects a point where the wiring 283 steps over a plane conductor excluded region in the lower plane conductor overlap configuration 286 based on the wiring-lower plane conductor overlap configuration 292, that is, the bridge points 293 and 294 shown in FIG. 17A are detected. In the way mentioned above, the detection of the bridge point in the wiring 284 completes.

When the detection of the bridge point of the wirings 283 and 284 is completed, the wiring check device 220 transmits information on the detection thereof to the output device 230. And the output device 230 outputs information on the received bridge point. As an output method of the information on the bridge point by the output device 230, there are a method of overlapping the bridge point on the wirings 283 and 284, and putting a round mark, and a method of putting a round mark on a plane conductor. The point which has a high risk of deterioration of an electromagnetic noise characteristic and should be taken a measure design with priority becomes clear by displaying in this way. Thereby, a measure design can be performed efficiently.

Further, in order to display a bridge point on the plane conductor, it is necessary to detect which layer the plane conductor in which the bridge point was detected is. This can be realized by the plane conductor detection unit 222 detecting information on a boundary line between a plane conductor formation region and an excluded region thereof (slit) in each layer, and by the bridge point detection unit 224 referring to this information. That is, the bridge point detection unit 224 should determine of which layer a plane conductor from which the bridge point was detected on the basis of the information of the boundary line between each layer is a plane conductor.

In the way mentioned above, the second wiring checking method is completed.

When emission of electromagnetic noise and coupling of electromagnetic noise entered from outside in a printed wiring board are considered, this method becomes very effective in checking a wiring formed in a substrate inner layer (a layer other than the top layer and the bottom layer in a laminated structure). That is, in the case of a wiring formed in a substrate inner layer, the risk of deteriorating an electromagnetic noise characteristic is different between the state where the wiring is not exposed to the outside of the printed wiring board in both the upper part and the lower part of the printed wiring board, and the state where it is exposed to the outside of the printed wiring board in at least one of the upper part and the lower part of the printed wiring board. However, the state that the wiring is exposed to the outside the printed wiring board in one of the upper part and the lower part of the printed wiring board cannot be grasped in case where only a plane conductor overlap configuration in which all the plane conductors included in the printed wiring board have overlapped is detected like the first wiring checking method. On the other hand, according to the second wiring checking method, the wiring-upper plane conductor overlap configuration and the wiring-lower plane conductor overlap configuration are detected respectively. Therefore, the state that the wiring is exposed to the outside of the printed wiring board in one of the upper part and the lower part of the printed wiring board can be grasped.

Further, in the second checking method, a plane conductor located in the same layer as the wiring may also be detected like the first checking method. In this case, the plane conductor located in the same layer as the wiring may be treated that it is included in both of the upper plane conductor overlap configuration and the lower plane conductor overlap configuration.

Next, as other example of the wiring checking method, a method to detect only a plane conductor within a predetermined distance from a wiring or within a predetermined number of layers among a plurality of plane conductors provided in the printed wiring board will be described. Below, the method to detect only a plane conductor within a predetermined distance from this wiring or within a predetermined number of layers will be called a third wiring checking method.

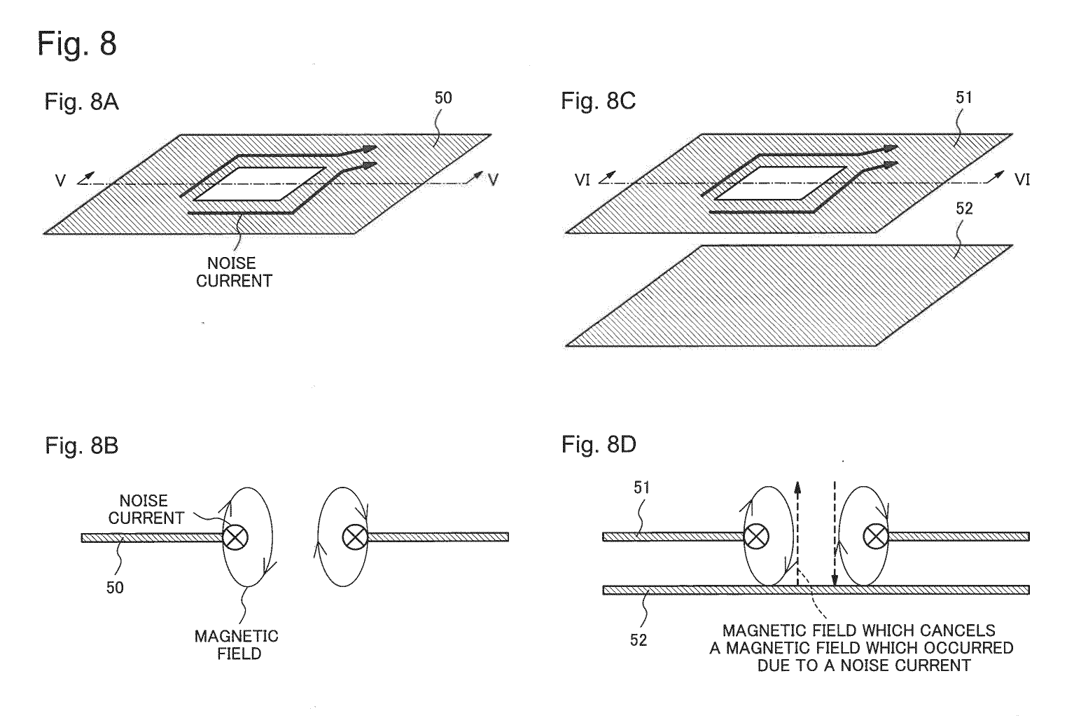

Further, the principle that the distance between the wiring and the plane conductor influences the magnitude of the risk of deteriorating an electromagnetic noise characteristic is as stated in case of the description about FIG. 8C and FIG. 8D. That is, as shown in FIG. 8D, the electromagnetic field around the slit is weakened by an electromagnetic field produced by an eddy current generated on the surface of the plane conductor 52 nearest to the plane conductor 51 located proximate the wiring. And an electromagnetic field produced by the noise current in the plane conductor 51 couples with the plane conductor 52 strongly as the distance between the plane conductor 51 and the plane conductor 52 is closer. That is, a risk of deteriorating an electromagnetic noise characteristic is reduced as the distance between the plane conductor 51 and the plane conductor 52 is closer.

From the reason mentioned above, when a wiring steps over a plane conductor excluded region (slit), the distance between this slit and the plane conductor arranged in other layer influences a risk of deteriorating an electromagnetic noise characteristic. Based on this, for example, the third wiring checking method such as a method of detecting plane conductors of the upper and the lower two layers from a layer where a wiring exists, or detecting plane conductors within 1 mm in a vertical direction from a wiring can be considered.

The details of the third wiring checking method will be described. Further, as a target printed wiring board on a wiring check, the printed wiring board 240 shown in FIG. 15A will be used like the second exemplary embodiment. Because Step 5 is similar to the first wiring checking method in the second exemplary embodiment, the description thereof will be omitted.

The plane conductor detection unit 222 detects plane conductors arranged: in a predetermined number of layers, for example, within two layers from a wiring; within a predetermined distance in a substrate laminating direction from a wiring, for example, within 1 mm from a layer including a wiring; or within 1 mm from a layer located proximate a layer including a wiring.

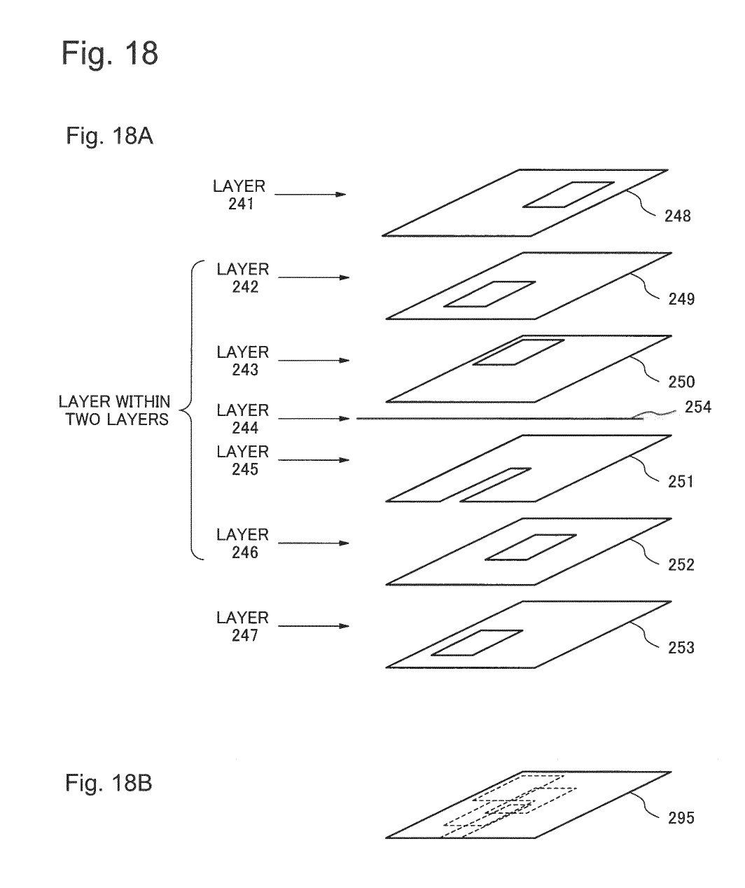

In this exemplary embodiment, it will be set so that plane conductors of layers within two layers from a layer including a wiring may be detected. In this case, the plane conductor detection unit 222 detects plane conductors 249-252 in layers 242, 243, 245 and 256 within two layers from a layer 244 including a wiring 254 as shown in FIG. 18A.

Next, the plane conductor overlap configuration detection unit 223 detects a plane conductor overlap configuration 295 which is a configuration in which the plane conductors 249-252 overlap one another. The plane conductor overlap configuration 295 is shown in FIG. 18B.

The bridge point detection unit 224 detects a wiring-plane conductor overlap configuration 296 which is a configuration in which the wiring 254 and the plane conductor overlap configuration 295 overlap one another.

And the bridge point detection unit 224 detects a point where the wiring 254 steps over a plane conductor excluded region in the plane conductor overlap configuration 295 based on the wiring-plane conductor overlap configuration 296.

Further, because the step in which the output device 230 outputs information on the bridge point after the bridge point detection unit 224 detects a bridge point is similar to other wiring checking methods, the description thereof will be omitted.

In the way mentioned above, the third wiring checking method is completed.

Further, although the plane conductor located in the same layer as the wiring also is also detected in the third wiring checking method like the first wiring checking method, it is not limited to this. That is, a plane conductor except a plane conductor located in the same layer as a wiring may be detected.

According to the third wiring checking method, a bridge point corresponding to the distance and the number of layers from the wiring can be detected Here, in a usual printed wiring board, one dielectric layer separating plane conductors has a thickness of a range from tens of micrometers to several millimeters. Accordingly, it is possible to check a wiring more precisely corresponding to the risk of deterioration of an electromagnetic noise characteristic by specifying the range to detect a plane conductor according to a number of layers or distance.

Further, a wiring check may be performed by a method which combined the third wiring checking method and the second wiring checking method. For example, a plane conductor corresponding to a distance or a number of layers from a wiring is detected, and the plane conductors to be detected may be separated into plane conductors located above the wiring and the plane conductors located below the wiring, and they may be detected, respectively.

Moreover, a wiring may be checked by combining a plurality of checking methods mutually among the first checking method, the second checking method, and the third checking method. For example, in a printed wiring board, some wiring may be checked by the first checking method, and other wiring may be checked by a method which combined the second checking method and the third checking method. Thus, it is possible to perform a wiring check flexibly corresponding to the type, the size or the like of a printed wiring board.

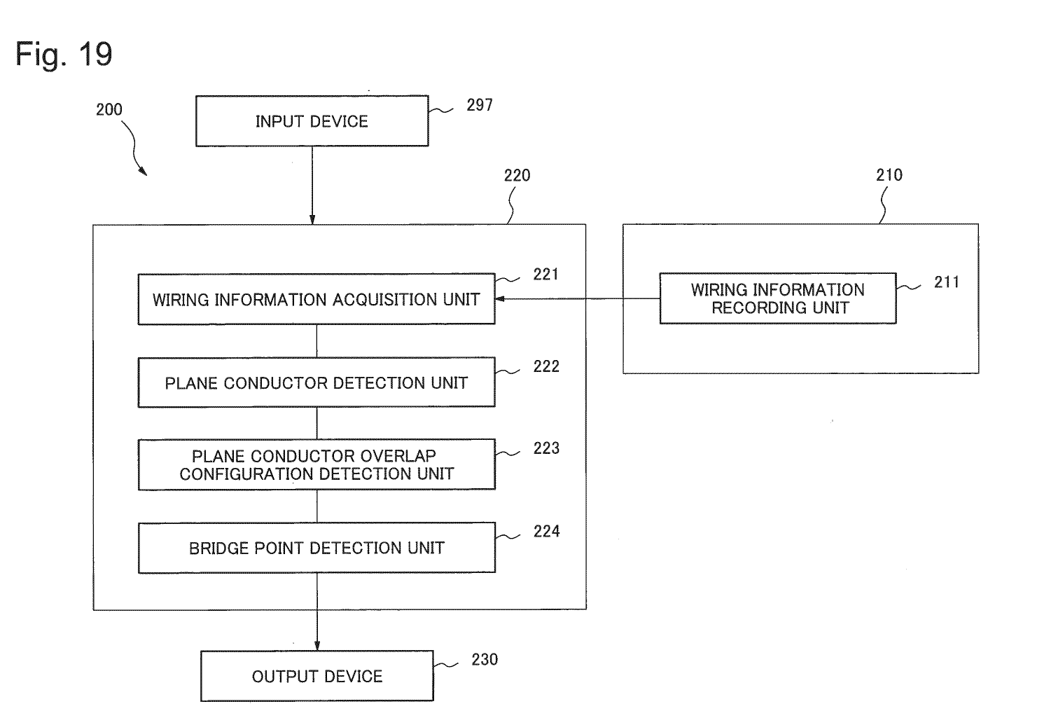

That is, according to the wiring check system 200, multiple wiring checking methods may be prepared, and a configuration that a designer selects which method is employed corresponding to a type of the substrate and the electromagnetic noise characteristic thereof may be used. For example, as shown in FIG. 19, an input device 297 may be added to the wiring check system 200 of the present invention shown in FIG. 13. And a wiring checking method may be selected, or a number of layers or distance of a plane conductor to be detected may be specified via the input device 297.

Using the methods mentioned above, by performing a wiring check, a bridge point with a low risk of deteriorating an electromagnetic noise characteristic will be excluded, and only a high-risk bridge point will be detected. Accordingly, the efficiency of a design which improves an electromagnetic noise characteristic can be realized. Thereby, the reliability of an electronic apparatus including a printed wiring board can be improved.

### Fourth Exemplary Embodiment

By the way, the inventor of the present application found that a risk of deteriorating an electromagnetic noise characteristic when a wiring steps over the plane conductor excluded region also depends on the area of the plane conductor excluded region. The basis thereof will be described based on a measurement result of an induced voltage by the inventor of the present application.

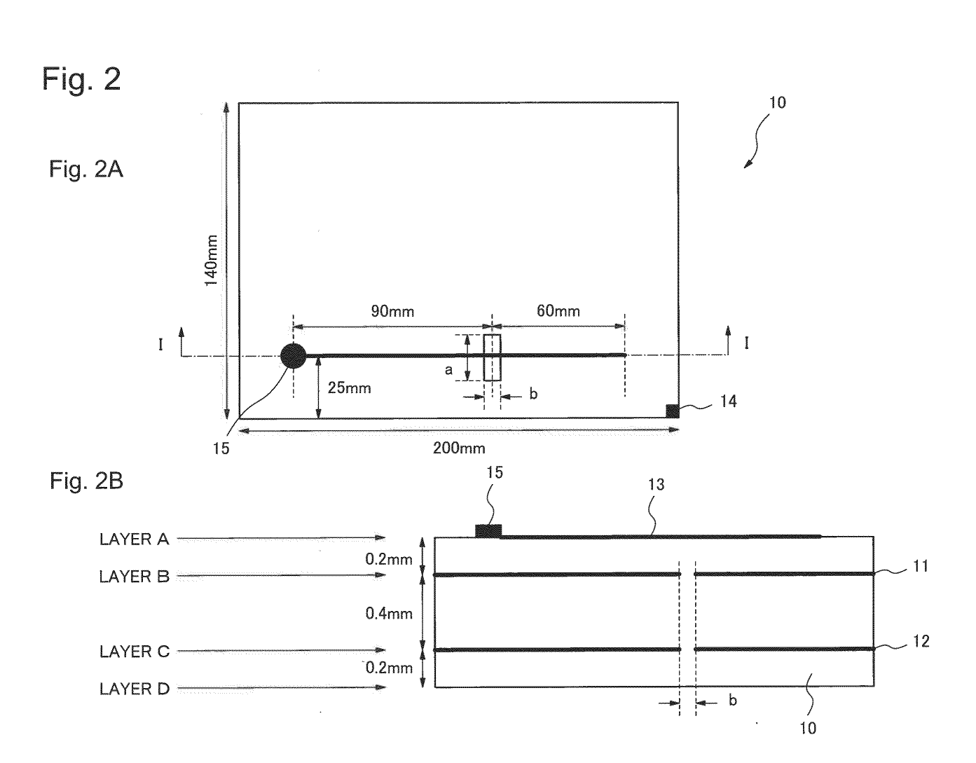

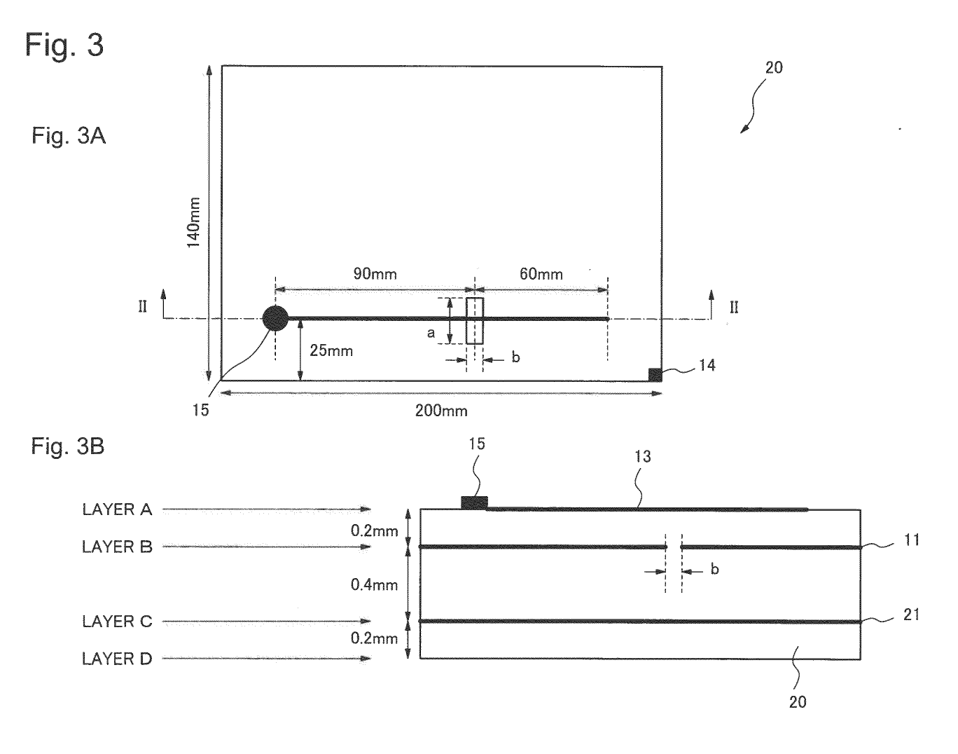

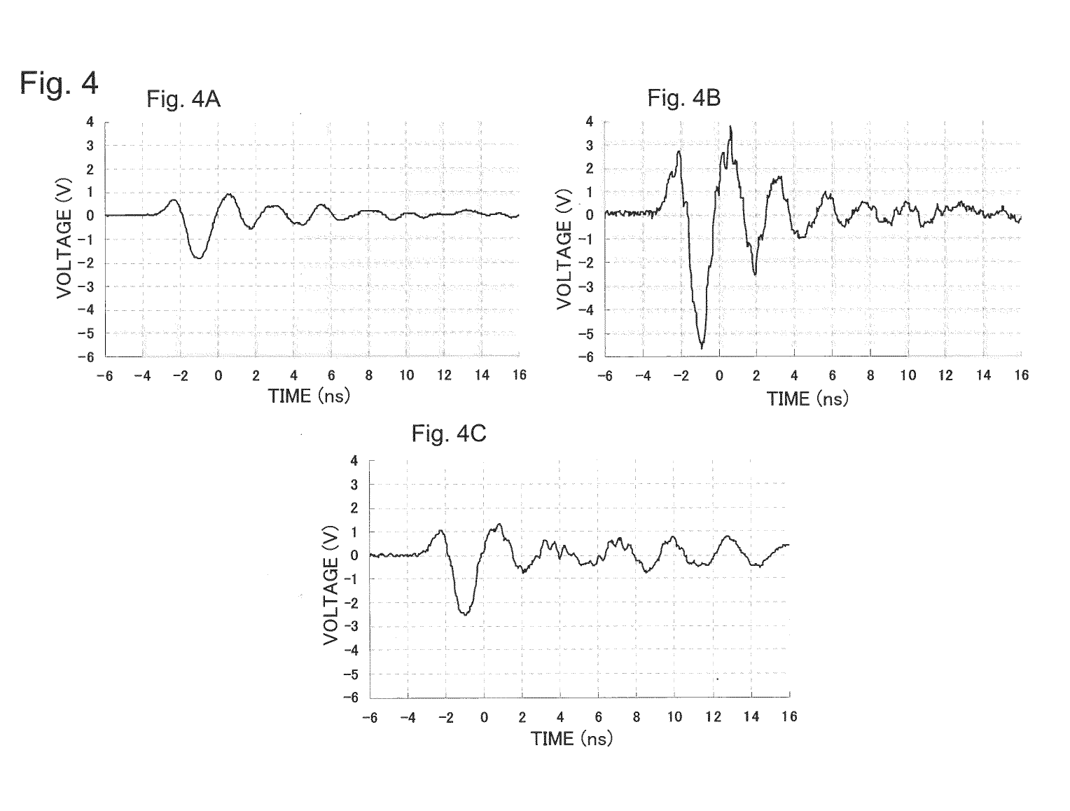

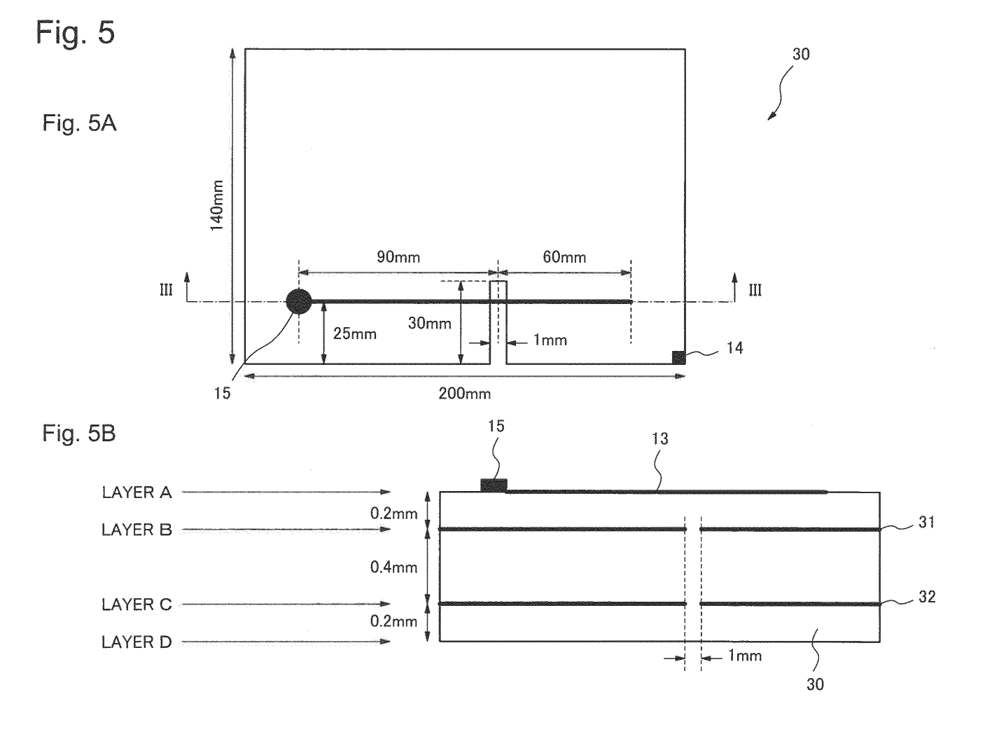

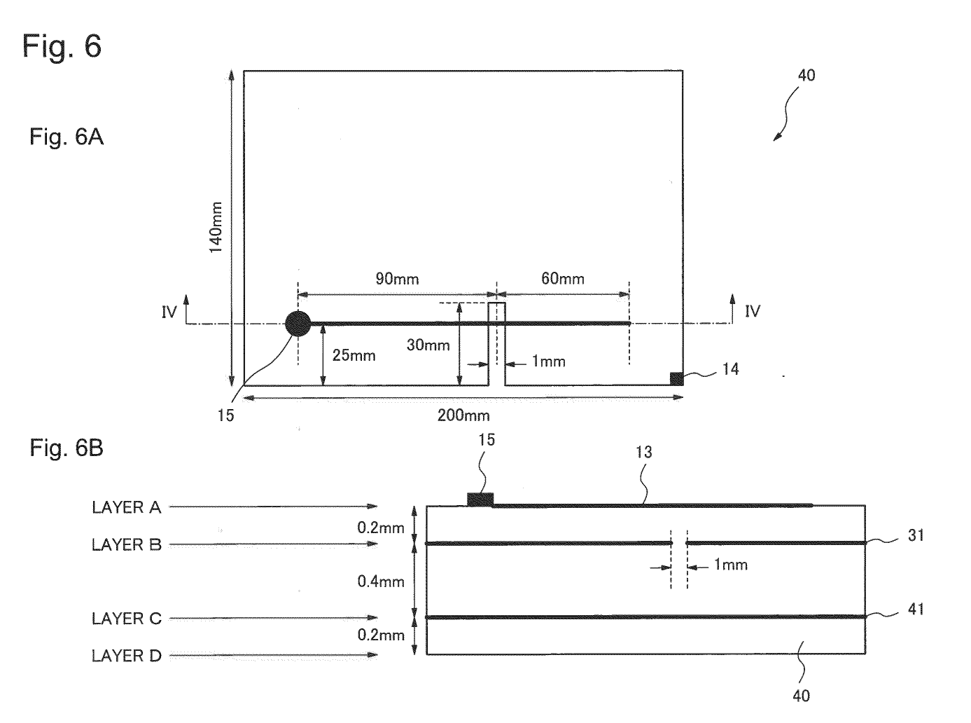

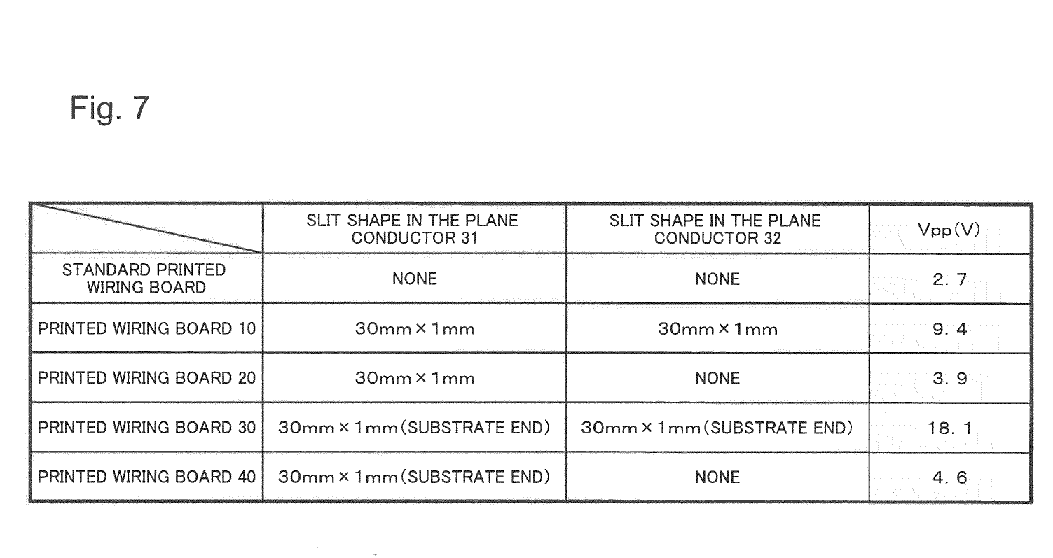

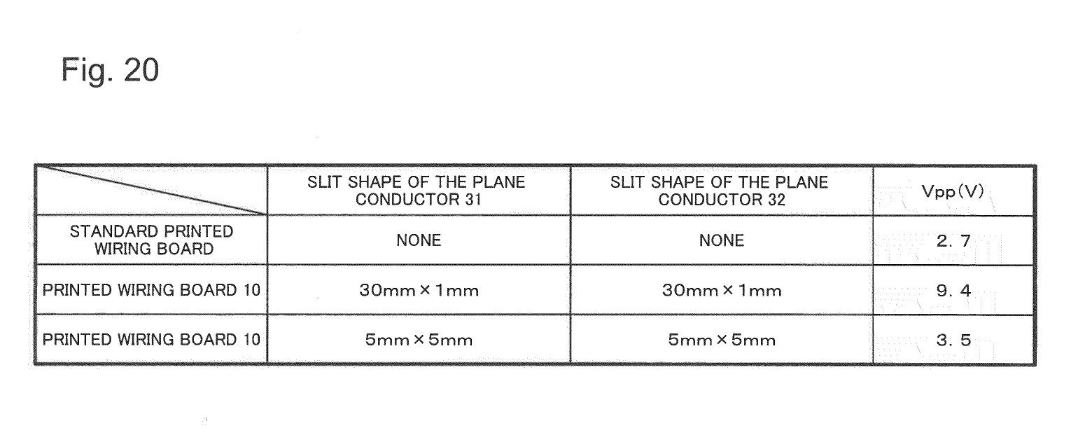

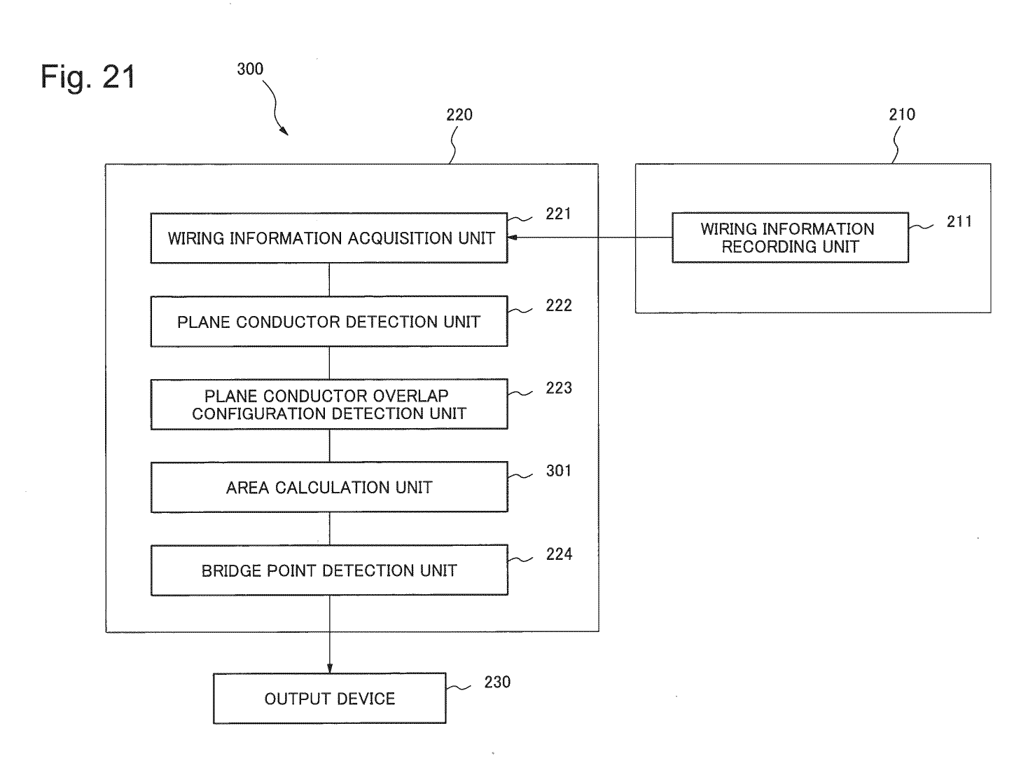

The configuration of a target printed wiring board of a measurement of an induced voltage is similar to the printed wiring board shown in FIG. 2. The area (a×b) of the slit provided in the plane conductors 11 and 12 of the printed wiring board 10 was changed, and it was verified. The verification result is shown in FIG. 20. Further, for comparison, the verification result of the standard printed wiring board in which any of the plane conductors does not have a slit is also shown in FIG. 20. It was found from FIG. 20 that the rate of increase of the voltage was about 1.3 times compared with the standard printed wiring board when the slit with the size of 5 mm×5 mm was formed in the plane conductors 11 and 12. On the other hand, it was found that the rate of increase of the voltage was about 3.5 times compared with the standard printed wiring board when the slit with the size of 30 mm×1 mm was formed in the plane conductors 11 and 12. That is, it was found that the risk of deteriorating an electromagnetic noise characteristic was low so that the area of the slit was small.

Accordingly, according to the fourth exemplary embodiment of the present invention, when a risk of deteriorating an electromagnetic noise characteristic is determined, the size of the plane conductor excluded region which a wiring steps over will be considered.

A wiring check system 300 according to this exemplary embodiment will be described using FIG. 21. The wiring check system 300 has a configuration in which an area calculation unit 301 was added to the wiring check system 200 in the second exemplary embodiment.

The area calculation unit 301 calculates the area of the plane conductor excluded region in the plane conductor overlap configuration.

And the bridge point detection unit 224 detects only a point where a wiring steps over a plane conductor excluded region having the areas beyond the predetermined size as a bridge point. That is, the bridge point detection unit 224 in this exemplary embodiment does not detect a point where the wiring steps over a plane conductor excluded region less than the predetermined area as a bridge point. For example, even if a wiring is stepping over a plane conductor excluded region with a size which is restored to an inside of a quadrangle of 3 mm×3 mm and a circle of 3 mm in radius, it is not detected as a bridge point.

Small plane conductor excluded regions (slits) below several mm square such as clearance holes for preventing conducting of penetration vias or pins of a mounting component, and a plane conductor exists in a general printed wiring board. And even if these slits are not covered by a plane conductor of other layer, the risk of deterioration of an electromagnetic noise characteristic is low. Therefore, by regarding a small slit as a plane conductor formation region, and excluding it from a detection target of a bridge point, a so-called pseudo error of a wiring check system can be reduced. Thereby, a high-risk point of deterioration of an electromagnetic noise characteristic can be detected more accurately.

Further, as the size of the slit which should be excluded from a detection target of a bridge point, a measurement result of an induced voltage of a wiring 13 shown in FIG. 20 will be one of indexes. As shown in FIG. 20, the increase of an induced voltage by a slit of 5 mm×5 mm is as small as about 1.3 times compared with a case where there is no slit. Here, in clearance holes or slits, each slit being formed of connecting several clearance holes, many of them fall within a range of 5 mm×5 mm. That is, even if these are excluded from a target on a wiring check, it is considered that the risk of deterioration of an electromagnetic noise characteristic is low. In an important wiring such as a reset wiring or a power supply wiring, noise is often suppressed by a filter element. Therefore, a slit with a size smaller than about 10 mm×10 mm, for example, may be excluded from a wiring check target, considering that a risk of deterioration of an electromagnetic noise characteristic is reduced sufficiently. Further, in order to design a substrate for which a risk of deterioration of an electromagnetic noise characteristic is reduced more, the setting value with the size of the excluded slit should be made small.

Thereby, the bridge point detection unit 224 in this exemplary embodiment can detect only a bridge point in which a risk of deteriorating an electromagnetic noise characteristic is high. Therefore, an electromagnetic noise characteristic of a printed wiring board can be improved more efficiently.

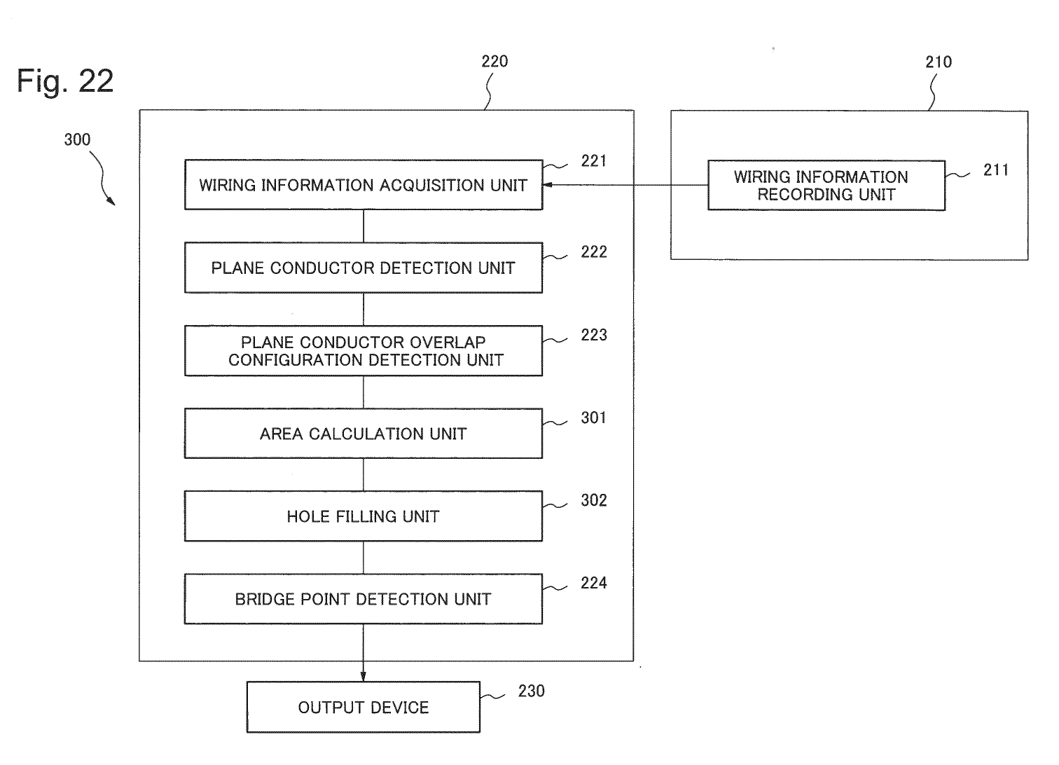

Further, as a method in detail for removing a plane conductor excluded region less than the predetermined area from a detection target, the wiring check device 220 may have a hole filling unit 302 as shown in FIG. 22. Further, the hole filling unit 302 performs a hole filling for a plane conductor excluded region less than the predetermined size based on a calculation result by the area calculation unit 301.

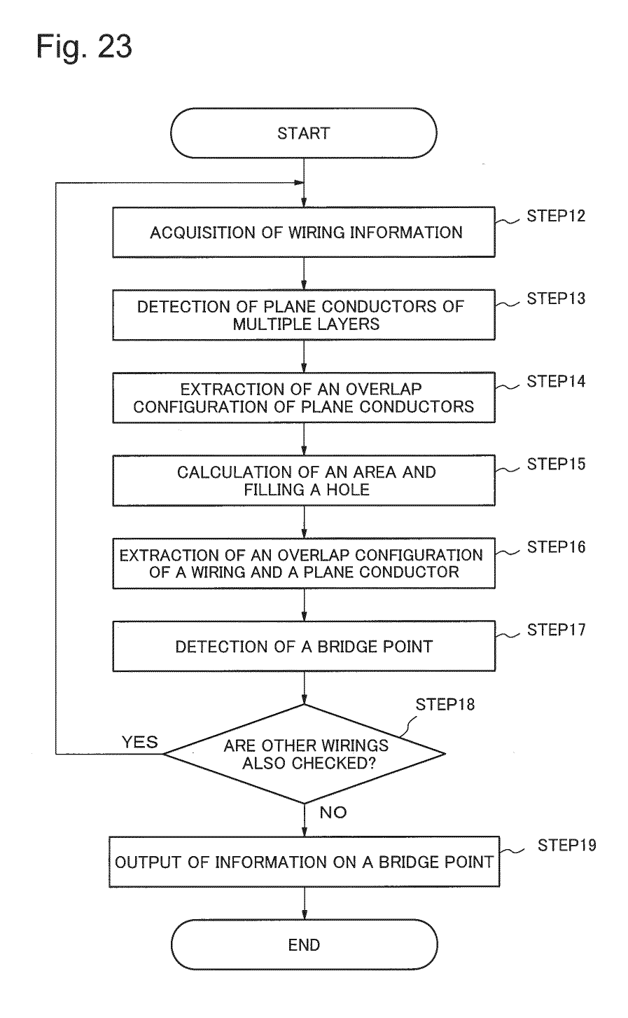

A more concrete operation method of the wiring check system 300 of this exemplary embodiment in a case of using the wiring check device 220 shown in FIG. 22 will be described using FIG. 23.

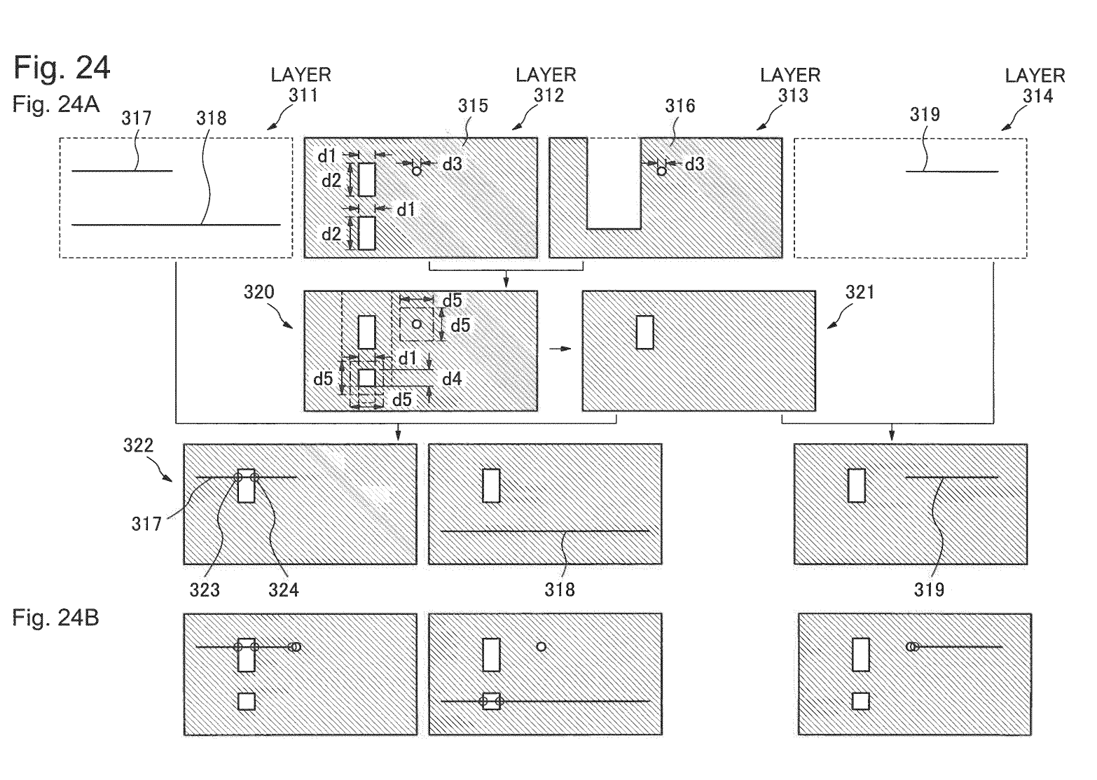

Further, as a target which performs a wiring check, a printed wiring board 310 shown in FIG. 24A will be used. The printed wiring board 310 has a four layered structure of laminating layers 311-314. Further, although not being illustrated, the layers 311-314 are laminated by this order, and the layer 311 is the top layer, and the layer 314 is the bottom layer. A top view of each layer of the printed wiring board 310 is shown in FIG. 24A. The layers 312 and 313 have plane conductors 315 and 316, respectively. The layers 311 and 314 have wirings 317-319. The wiring 317 of the layer 311 is wired in the layer 314 via a signal via and continues with the wiring 319. Moreover, two slits of the size d1×d 2 are formed in the plane conductor 315 of the layer 312. A via which connects the wiring 317 to the layer 314 from the layer 311 penetrates the layer 312 and the layer 313. Therefore, clearance holes of a diameter d3 for avoiding a connection of the via and the plane conductors 315 and 316 are formed in the layer 312 and the layer 313.

Further, it is assumed that the design information on the printed wiring board 310 to which a wiring check is performed is recorded in advance in the design information recording unit 221.

First, the wiring information acquisition unit 221 acquires wiring information on the wiring 317 (Step 12).

And the plane conductor detection unit 222 detects the plane conductors 315 and 316 included in the multiple layers (layers 312, 313 and 314) including the layer 312 nearest to the layer 311 having the wiring 317 (Step 13). The plane conductor overlap configuration detection unit 223 detects a plane conductor overlap configuration 320 which is a configuration in which the plane conductors 315 and 316 overlap one another (Step 14). In a plane conductor overlap configuration 320, a part of one of the slits formed in the plane conductor 315 of the layer 312 is covered by the plane conductor 316 of the layer 313, and its size will be d1×d4. Because other slit and the clearance hole are not covered by the plane conductor 316 of the layer 313, its size is not changed.

Next, the area calculation unit 301 calculates the area of the plane conductor excluded region in the plane conductor overlap configuration 320 (Step 15). And the hole filling unit 302 performs hole filling for the plane conductor excluded region of the area smaller than the predetermined value recorded in the recording device 210 (Step 15). The plane conductor overlap configuration 320 will be a plane conductor overlap configuration 321 by performing hole filling by the hole filling unit 302. Here, the hole filling is performed to the slit of d1×d4 smaller than the quadrangle of a default d5 (d1, d3 and d4<d5<d2) which the storage device 210 records, and the clearance hole with a diameter d3.

Next, the bridge point detection unit 224 detects the wiring-plane conductor overlap configuration 322 in which the wiring 317 and the plane conductor overlap configuration 321 overlap one another (Step 16).

And the bridge point detection unit 224 detects the points (bridge points 323 and 324) where the wiring 317 steps over the plane conductor excluded region in the plane conductor overlap configuration 321 based on the wiring-plane conductor overlap configuration 322 (Step 17).

And a similar step is also performed to the wirings 318 and 319, and points where the respective wirings step over the plane conductor excluded region in the plane conductor overlap configuration 321 is detected. However, because the wirings 318 and 319 do not step over the plane conductor excluded region in the plane conductor overlap configuration 321, the bridge point is not detected.

And when a wiring check is completed about all wirings (in Step 18, NO), the information on the bridge point which the bridge point detection unit 224 detected is transmitted to the output device 230. And the output device 230 outputs the information on the received bridge point (Step 19). Thereby, operation of the wiring check system in this exemplary embodiment is completed.

Further, the detection result of the bridge point in the case where the plane conductor excluded region less than the predetermined area was not performed by the hole filling unit 302 is shown in FIG. 24B for reference. In FIG. 24B, a point where a wiring steps over a small clearance hole whose diameter is generally less than hundreds of micrometers is also detected. That is, it is also detected about a bridge point with a low risk of deterioration of an electromagnetic noise characteristic.

On the other hand, the wiring check system 300 in this exemplary embodiment detects only a point where a wiring steps over a plane conductor excluded region larger than the predetermined area. Therefore, a point of a low risk of deterioration of an electromagnetic noise characteristic is not detected any more, and a point with a high risk which should perform improvement design is detected more accurately.

An input device may be added to the configuration of the wiring check system 300 shown in FIG. 22. And the size of the area of the plane conductor excluded region excluded from a target on a wiring check may be specified using the input device.

Further, in this exemplary embodiment, a bridge point detected may be different by whether a plane conductor arranged in the same layer as a wiring is included in a plane conductor overlap configuration. This is because the area of the plane conductor excluded region in the plane conductor overlap configuration becomes small by including the plane conductor arranged in the same layer as the wiring, and it may be performed hole filling by the hole filling unit 302. That is, a point where a risk of deteriorating an electromagnetic noise characteristic is high can be detected more correctly by including the plane conductor arranged in the same layer as the wiring in the plane conductor overlap configuration.

### Fifth Exemplary Embodiment

By the way, the inventor of the present application found by an electromagnetic field simulation that a risk of deteriorating an electromagnetic noise characteristic may not be reduced in spite of a slit of a plane conductor located proximate a wiring being covered by other plane conductor. The contents and the result of the electromagnetic field simulation will be described.

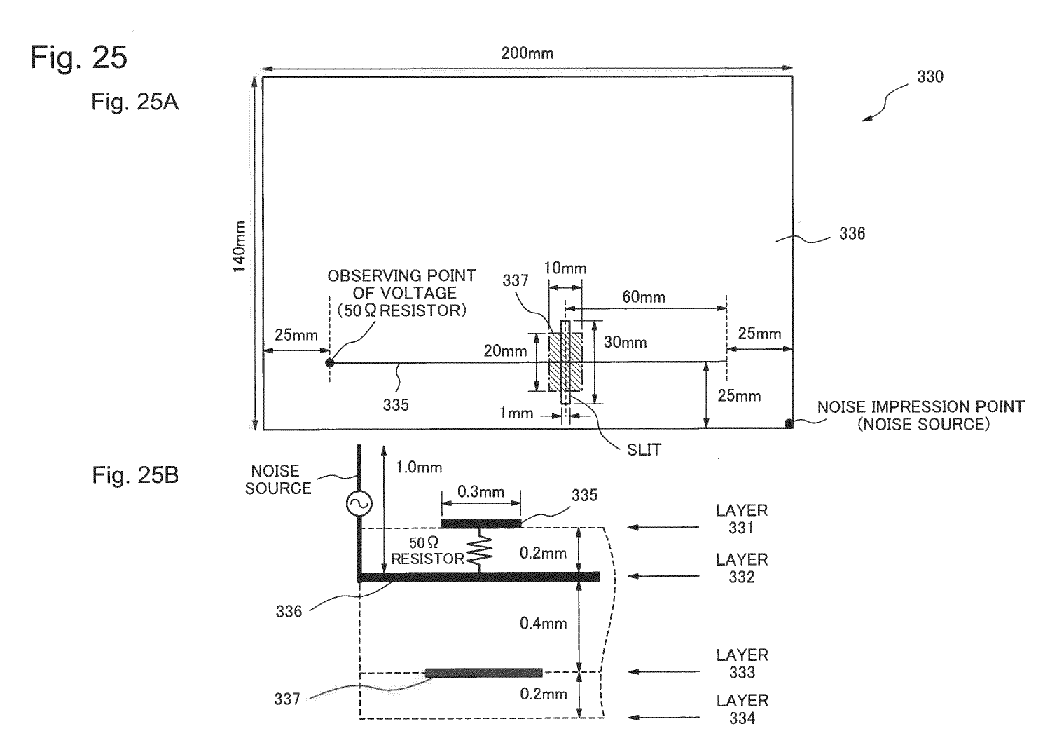

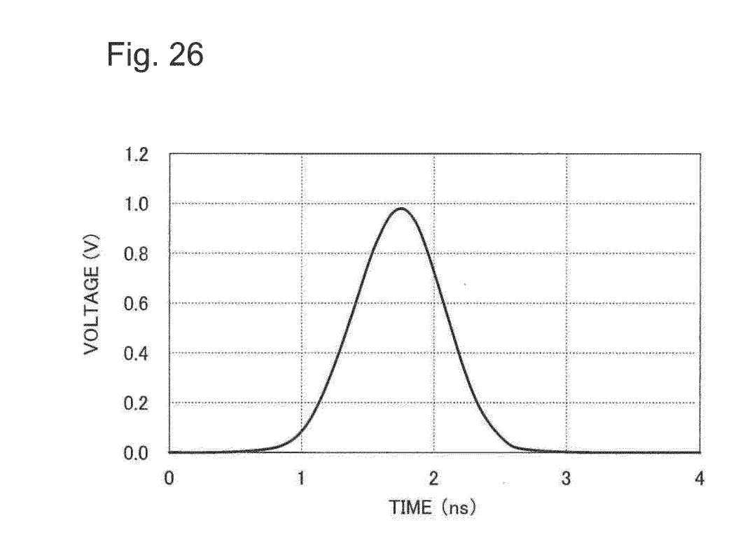

FIG. 25 shows a simulation model. FIG. 25A shows a top view of a printed wiring board 330 which became a simulation model. FIG. 25B shows a left side view of the printed wiring board 330. The printed wiring board 330 is a size of 140 mm×200 mm and a thickness of 0.8 mm and has a four layered configuration (layers 331-334). A wiring 335 is arranged in the layer 331 which is the top layer, a plane conductor 336 is arranged in the second layer 332, and a plane conductor 337 is arranged in the third layer 333. A dielectric substrate imitated a glass epoxy board (FR-4), and the dielectric constant was set to 4.3 and the dielectric dissipation factor was set to 0.025. The plane conductor 336 has a slit of 30 mm×1 mm. The plane conductor 337 has a slit with a size of 20 mm×10 mm which has the same center position as the slit of the plane conductor 336. A linear antenna of 1 mm in length was arranged at the edge of the printed wiring board 330 as a noise source, and a voltage source was arranged in the center. An input to the voltage source was made a pulse waveform of the maximum voltage 1 V shown in FIG. 26. In one end of the wiring 335, a 50Ω resistor was inserted between the plane conductor 336. And a voltage induced in the wiring by noise impression was observed. Further, other end of the wiring 335 was opened without connecting anything.

First, a difference in a coupling voltage to the wiring 335 by presence or absence of the plane conductor 337 was investigated using such simulation model. Further, the FDTD (Finite Difference Time Domain) method which is an electromagnetic field analysis method of the time domain type was used for the simulation.

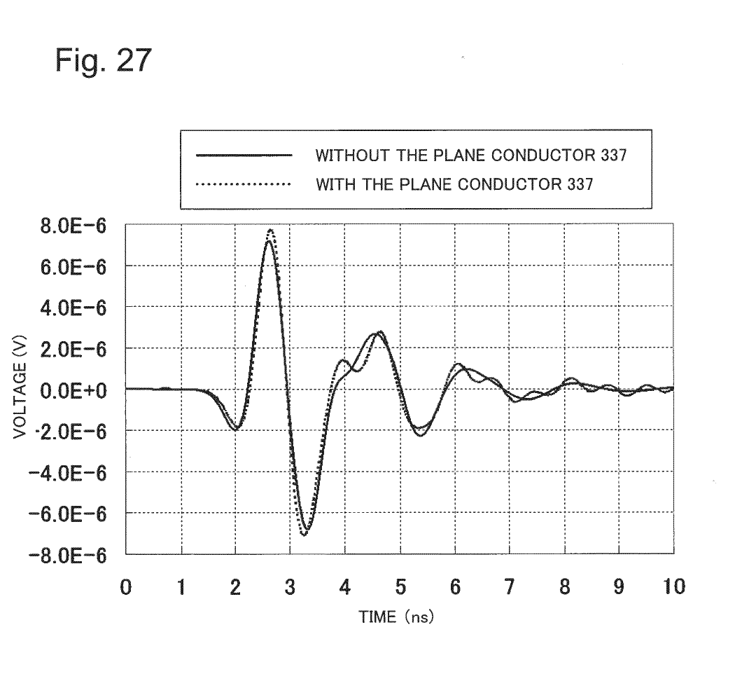

A result of the simulation is shown in FIG. 27. Even if the plane conductor 337 is arranged, it is found from FIG. 27 that the coupling voltage to the wiring 335 is not suppressed and increases rather a little. That is, although the slit of the plane conductor 336 is partially covered by the plane conductor 337, a risk of deterioration of an electromagnetic noise characteristic is increased. That is, although a depression effect of a noise, i.e., a depression effect of the coupling voltage to the wiring, is obtained by the existence of the plane conductor which covers a slit as shown in FIG. 8, it was found that such depression effect may not be obtained by the size of the plane conductor or the positional relationship with the slit.

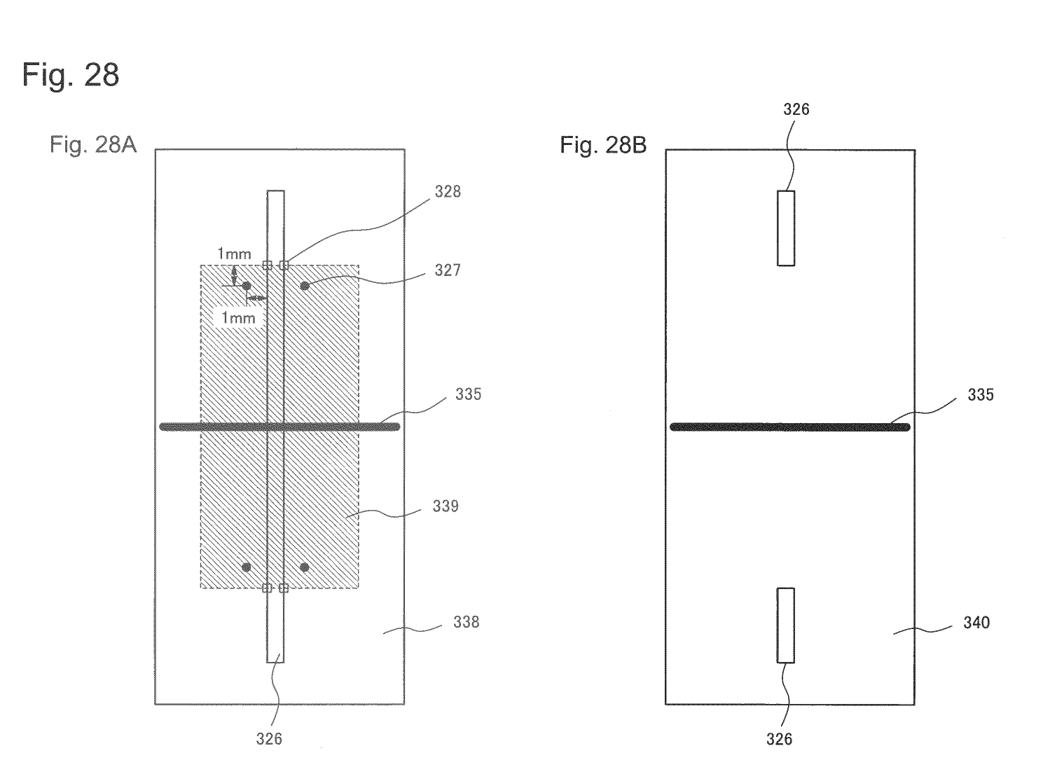

Here, in a general printed wiring board, plane conductors are connected mutually by a large number of vias or capacitors. Accordingly, as shown in FIG. 28, a simulation was performed about a case where a plane conductor 338 and a plane conductor 339 were connected by vias 327. FIG. 28A shows connecting locations of the plane conductor 338 and the plane conductor 339. Further, because the plane conductor 339 was located in a lower layer than the plane conductor 338, only the part thereof was actually visible, but it was shown by a dotted line for description. As shown in FIG. 28A, the plane conductor 338 and the plane conductor 339 are connected at four locations by the vias 327. These vias 327 are 0.1 mm in diameter. These vias 327 have been arranged in the positions of 1 mm vertically and horizontally, respectively from the intersection 328 of the periphery of the slit 326 of the plane conductor 338, and the boundary line of the periphery of the slit of the plane conductor 339. Further, the periphery of the slit is the boundary line between the plane conductor formation region and the plane conductor excluded region. In order to consider a depression effect of a noise by connection between the plane conductor 338 and the plane conductor 339, a simulation was performed also about the plane conductor 340 which has a configuration shown in FIG. 28B where the plane conductor 336 and the plane conductor 337 overlap one another.

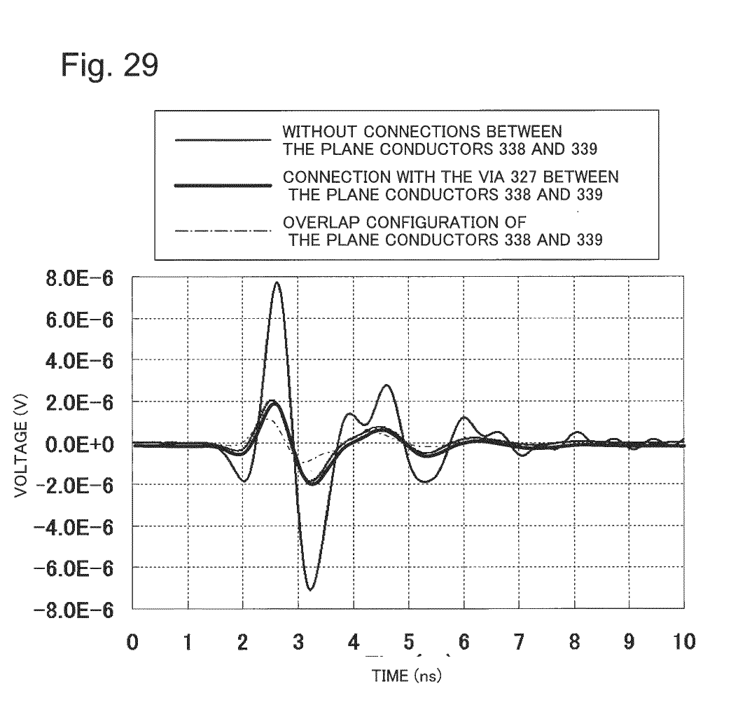

A result of the simulation is shown in FIG. 29. As shown in FIG. 29, when the plane conductor 338 and the plane conductor 339 were connected by the vias 327, it was found that the induced voltage became no more than ⅓, compared with the case without connection by the vias. It was found that this value is comparable as a value of the induced voltage in the configuration in which the plane conductor 338 and the plane conductor 339 overlapped one another.

That is, it was found that the risk of deteriorating an electromagnetic noise characteristic was reduced when the plane conductors were electrically connected mutually, so that it could be deemed that it was equal to the case where two plane conductors overlapped one another. This is considered because a noise current which flows through the periphery of the slit of the plane conductor 338 comes to flow into the plane conductor 339 by connecting the plane conductors by the vias, and a path of the noise current will approach a case in which both plane conductors overlap one another. When a capacitor is used for connecting between plane conductors, the same effect as the case of connecting by vias is obtained. That is, when the capacitor is used for connecting between the plane conductors, a path of a noise current is formed between the two plane conductors.

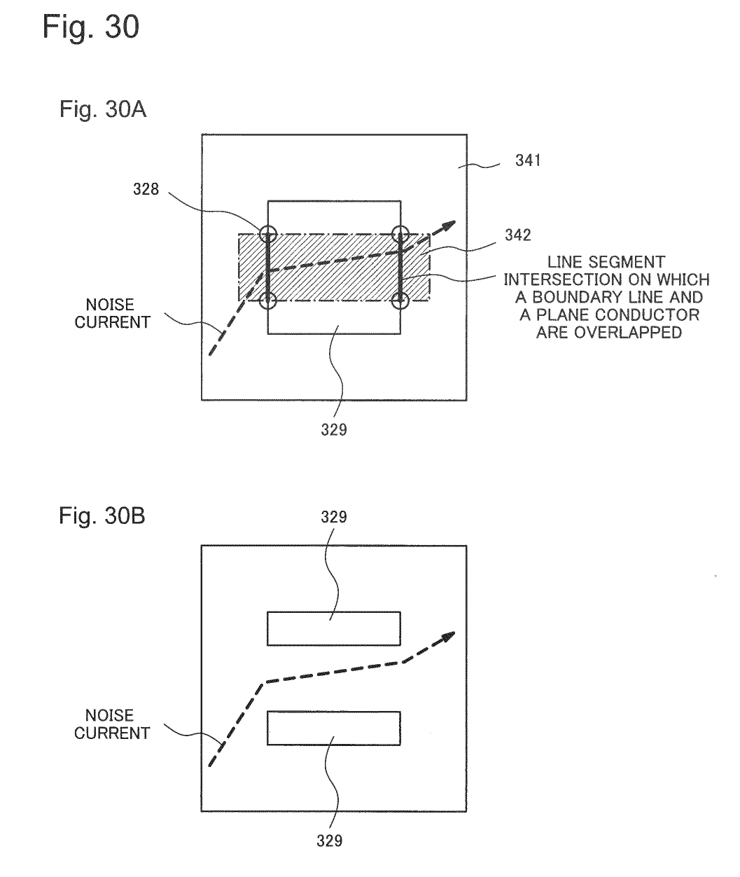

Further, in order to deem that two plane conductors connected by vias or a capacitor is the same as the configuration in which both of them overlap one another, an arrangement of the via or the capacitor becomes important. Here, a path of a noise current which flows through a plane conductor is considered. FIG. 30A is a diagram viewing a plane conductor 341 having a slit 329, and a plane conductor 342 which was formed in a different layer from the plane conductor 341 from a top face. Further, because the plane conductor 342 was located in a lower layer than the plane conductor 341, only the part thereof was actually visible, but it was shown by a dotted line for description. As shown in FIG. 30A, the plane conductor 342 covers the part of the slit 329 of the plane conductor 341. FIG. 30B shows a configuration in which the plane conductor 341 and the plane conductor 342 overlap one another. In FIG. 30A and FIG. 30B, in order for a noise current to flow through the same path, vias or capacitors may be arranged along a line segment on which the periphery of the slit 329 of the plane conductor 341 of FIG. 30A and the plane conductor 342 overlap, and between the plane conductors may be connected. Thereby, it can be deemed that two plane conductors of FIG. 30A are the same as the configuration in which two plane conductors shown in FIG. 30B overlap one another. In the electromagnetic field simulation mentioned above, it is confirmed that the almost same result as the configuration in which two plane conductors shown in FIG. 28B overlapped one another is obtained, when the vias were arranged in only the neighborhood of the intersection of the boundary line between the plane conductor formation region and the plane conductor excluded region of the two plane conductors, as shown in FIG. 28A.

From this, in order to deem that two plane conductors are similar to the configuration where both overlap one another, vias or capacitors should just be arranged in the neighborhood of the line segment where a boundary line between a plane conductor formation region and a plane conductor excluded region in a layer located proximate the wiring and a plane conductor of other layer overlap. Or, vias or capacitors may be arranged in the neighborhood of the intersection of a boundary line between a plane conductor formation region and a plane conductor excluded region in a layer located proximate the wiring and a boundary line between a plane conductor formation region and a plane conductor excluded region in other layer. Further, a path of a noise current becomes shortest so that the vias or the capacitors are near a line on which a boundary line and other plane conductor overlap or an intersection of boundary lines. That is, it approaches a current path in the configuration in which two plane conductors overlap one another. On the other hand, when vias or capacitors are away from the line segment on which a boundary line and other plane conductor overlap, or the intersection of boundary lines, a path of a noise current becomes longer. That is, a difference from the current path when two plane conductors overlap one another becomes larger. Therefore, as for a via or a capacitor, it is desirable that it is close to a line segment with which a boundary line between a plane conductor formation region and a plane conductor excluded region and other plane conductor overlap, and an intersection of a boundary line between a plane conductor formation region and a plane conductor excluded region.

Here, the range of an arrangement position of a via or a capacitor with which two plane conductors can be deemed to be equivalent to the configuration in which both of them overlap one another. As for a path of a noise current, when a phase of a current by a path of a noise current becoming long is taken into consideration, it is desirable to adopt 1/10 to less than 1/20 of a wave length of the noise current so that it may become sufficiently small compared with the wave length thereof. For example, when a maximum frequency of a noise current is set to 1 GHz, a dielectric substrate is set to FR-4, and a wavelength shortening effect is taken into consideration, it will be about 14 mm by 1/10 of the wave length, and will be about 7 mm by 1/20.

Further, in a general printed wiring board, vias or capacitors are arranged a lot in about several centimeters of interval from several millimeters. Therefore, as observed by the simulation shown in FIG. 27, it is very rare for a situation where there is no connection of a plane conductor and the noise suppression effect by the plane conductor 337 is not obtained to generate. In particular, in a ground plane of a multi-layer printed wiring board, a large number of vias are arranged in order to eliminate a potential difference between the plane conductors, or in order to suppress noise propagation between the plane conductors. Therefore, a wiring check system which excludes a power plane in advance, detects only a ground plane, and detects a plane conductor overlap configuration in the step of detecting the plane conductor may be constituted. Thereby, it is possible to exclude in advance a plane conductor from which noise suppression effect is not obtained. However, regardless of a type of plane conductor, it is useful to also take into consideration connection of plane conductors with vias or capacitors in order to carry out a wiring check of the whole printed wiring board.

From the above, when detecting a risk of deterioration of an electromagnetic noise characteristic, it can be said that it is desirable to also take into consideration connection of plane conductors by a via, a capacitor, or the like.

Accordingly, in the fifth exemplary embodiment of the present invention, a wiring check system which can also take into consideration connection of plane conductors by a via, a capacitor, or the like.

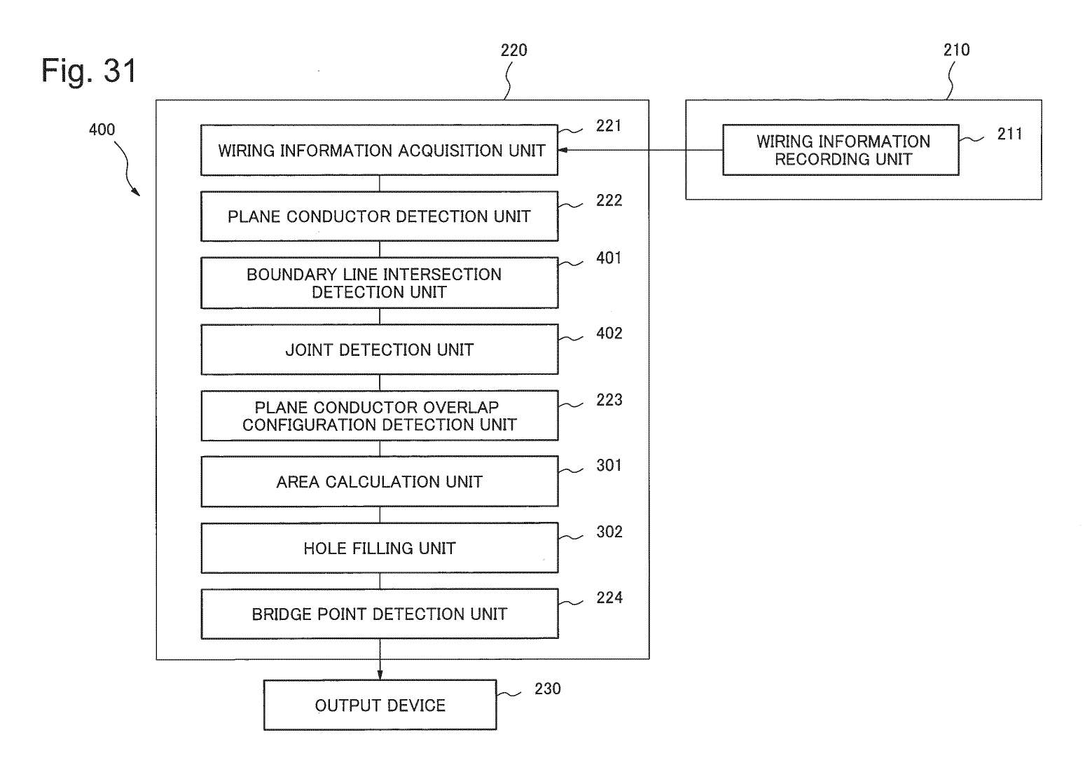

A wiring check system 400 in this exemplary embodiment is shown in FIG. 31. The wiring check system 400 has a configuration which added a boundary line intersection detection unit 401 and a joint detection unit 402 to the wiring check system 300 in the fourth exemplary embodiment.

The boundary line intersection detection unit 401 detects a boundary line between a plane conductor formation region and a plane conductor excluded region in the respective layers where plane conductors which the plane conductor detection unit 222 detected are arranged. And the boundary line intersection detection unit 401 detects an intersection of a boundary line in a case where plane conductors of each layer overlap one another.

The joint detection unit 402 detects presence or absence of a connection between a plurality of plane conductors within a predetermined distance from the intersection of the boundary line which the boundary line intersection detection unit 401 detected. Further, for example, a connection between the plane conductors is realized by a via or a capacitor.

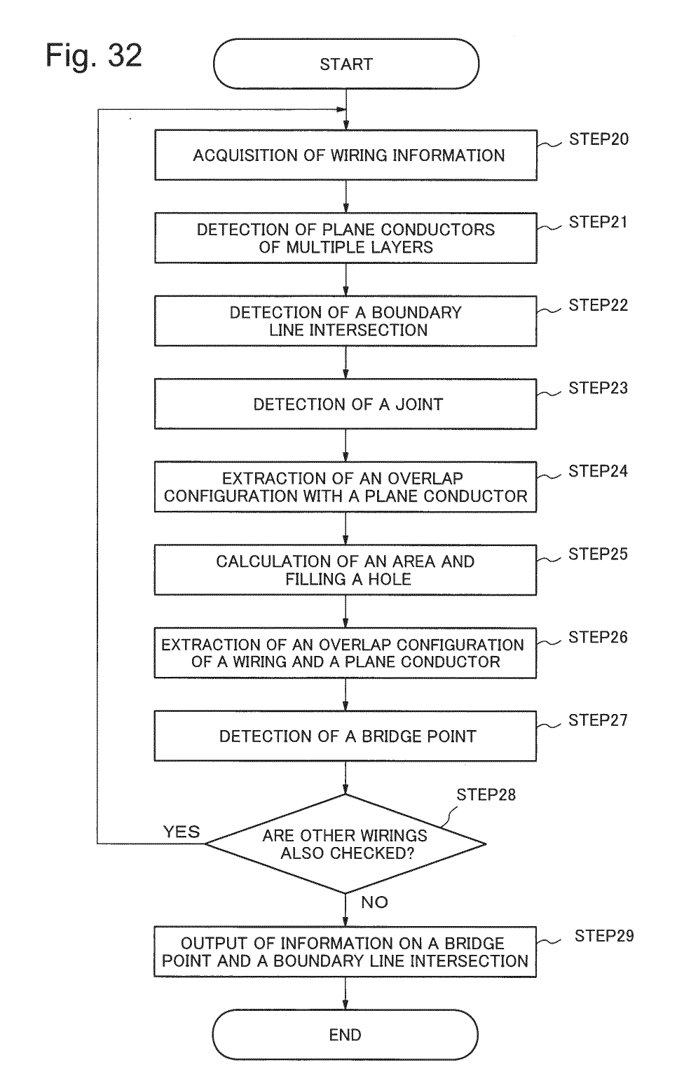

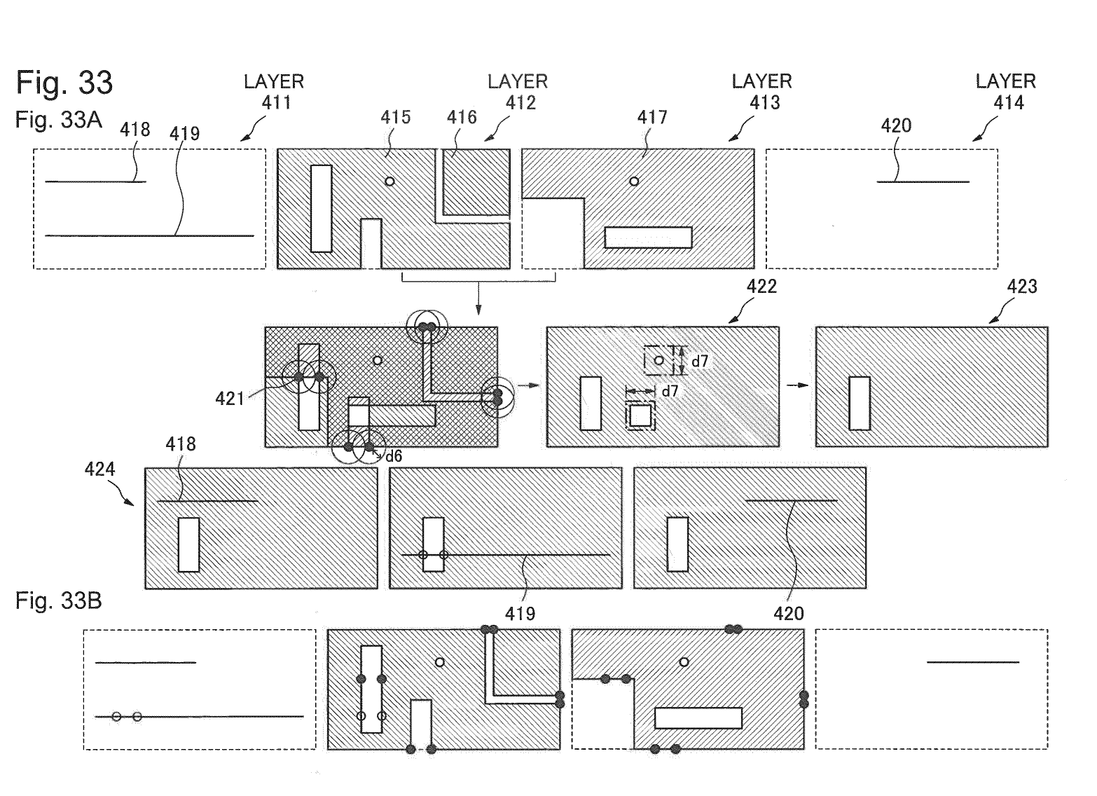

Next, operation of the wiring check system 400 according to this exemplary embodiment will be described using FIG. 32. As a target on a wiring check by the wiring check system 400, a printed wiring board 410 shown in FIG. 33 will be used. The slant line part in FIG. 33 shows a plane conductor formation region which is a region where a plane conductor was formed. A dotted line shows a contour of the printed wiring board 410. The printed wiring board 410 has a 4 layered structure of the laminated layers 411-414. Further, although not being illustrated, the layers 411 to 414 are laminated by this order, and the layer 411 is a top layer, and the layer 414 is a bottom layer. A top view of each layer of the printed wiring board 410 is shown in FIG. 33A. The layers 412 and 413 have plane conductors 415-417. The layers 411 and 414 have wirings 418-420. The wiring 418 is wired in the layer 414 via a signal via and continues with the wiring 420. Further, it is not connected by a via or a capacitor between the plane conductors 415-417 of the layers 412 and 413.

Further, it is assumed that the design information on the printed wiring board 410 to which a wiring check is performed is recorded in the design information recording unit 211 in advance.

First, the wiring information acquisition unit 221 acquires wiring information on the target wiring 418 on a wiring check (Step 20). And the plane conductor detection unit 222 detects the plane conductors 415-417 of multiple layers (layers 411-414) including the nearest layer 412 to the layer 411 having the wiring 418 (Step 21).

And the boundary line intersection detection unit 401 detects a boundary line between a plane conductor formation region and a plane conductor excluded region in the layers 412 and 413 (Step 22). And the boundary line intersection detection unit 401 detects an intersection of a boundary line in a case of overlapping the plane conductors 415-417. In the printed wiring board 410, the boundary line intersections which the boundary line intersection detection unit 401 detects are eight boundary line intersections 421 shown in FIG. 33A by the black circles.

Next, the joint detection unit 402 detects a joint where it is within a predetermined distance from a boundary line intersection 421 (Step 23). That is, it is detected whether two plane conductors are connected electrically by a predetermined within a predetermined range from the boundary line intersection 421. Specifically, it is detected whether vias or capacitors which connect the plane conductors 415-417 exist within the range of the predetermined value d6 recorded in the recording device 210 centering on the boundary line intersection 421. Moreover, when a joint is not detected within the predetermined range from the boundary line intersection, the joint detection unit 402 detects information on the boundary line intersection. Information on a boundary line intersection is a coordinate of a boundary line intersection or an arrangement of a layer having the boundary lines. Here, in the printed wiring board 410, a joint which connects between the plane conductors does not exist. Therefore, information about all boundary line intersections among eight boundary line intersections 421 is detected.

The plane conductor overlap configuration detection unit 223 detects a plane conductor overlap configuration 422 which is a configuration in which the plane conductors 415-417 which the plane conductor detection unit 222 detected overlap one another (Step 24). And because a plane conductor excluded region smaller than a quadrangle of a predetermined value d7 recorded in the storage device 210 is deemed as a plane conductor formation region, it is performed hole filling, and it will be a plane conductor overlap configuration 423 (Step 25). And the bridge point detection unit 224 detects a wiring-plane conductor overlap configuration 424 which is a configuration in which the wiring 417 and the plane conductor overlap configuration 423 overlap one another (Step 26). Moreover, the bridge point detection unit 224 detects a point where the wiring 417 steps over a plane conductor excluded region in the plane conductor overlap configuration 423 based on the wiring-plane conductor overlap configuration 424 (Step 27). Similarly, a bridge point is also detected about the wirings 419 and 420.

When a check about all the wirings is finished (it is NO in Step 28), the wiring check device 220 transmits information about the bridge points which the bridge point detection unit 224 detected to the output device 230.

And the wiring check device 220 also transmits information about the boundary line intersection in which a joint was not detected within a predetermined range among eight boundary line intersections 421 to the output device 230. Information about the boundary line intersection is a coordinate of a boundary line intersection or information about a plane conductor having boundary lines which the joint detection unit 402 detected.

And the output device 230 outputs information about the bridge point and information about a boundary line intersection in which a joint was not detected within the predetermined range (Step 29).

An example of information which the output device 230 outputs is shown in FIG. 33B. In FIG. 33B, the bridge point was shown with a white circle, and the boundary line intersection in which a joint was not detected within the predetermined range was shown with a black circle. And the boundary line intersection in which a joint was not detected within the predetermined range is displayed by arranging the boundary line intersection on the plane conductor. By adopting such display, a part in which a via or a capacitor should be arranged in a design phase of a printed wiring board becomes clear. And the noise suppression effect by a plane conductor which covers a slit can be obtained more certainly by arranging a via or a capacitor in accordance with this result. Therefore, the efficiency of a measure design which improves an electromagnetic noise characteristic can be increased.

Further, the boundary line intersection detection unit 401 may detect not only an intersection of a boundary line but also a line segment on which a boundary line on the layer nearest to the wiring and a plane conductor in other layer overlap. Below, a line segment on which a boundary line on the layer nearest to the wiring and a plane conductor in other layer overlap is called an overlap line segment. In this case, the joint detection unit 402 detects whether a via or a capacitor exists within a predetermined range from the overlap line segment. And in the output by the output device 230, an overlap line segment from which a via or a capacitor was not detected within a predetermined range may be displayed by arranging on the plane conductor.

And, the second wiring checking method or the third wiring checking method which was described in the third exemplary embodiment may be combined with the wiring checking method in this exemplary embodiment. That is, a plane conductor located above a layer having a wiring, and a plane conductor located below the layer may be distinguished and detected. A plane conductor may be detected within a predetermined distance or within a predetermined number of layers from a layer having a wiring.

As mentioned above, when a risk of deterioration of an electromagnetic noise characteristic is detected in this exemplary embodiment, a connection between the plane conductors by vias or capacitors can also be taken into consideration. Therefore, an electromagnetic noise characteristic can be improved more efficiently.

Moreover, it goes without saying that the first exemplary embodiment to the fifth exemplary embodiment can be achieved by preparing a recording medium which recorded a program code of software which realizes a function of each exemplary embodiment, reading the program code stored in the recording medium with a general purpose computer, and operating as a wiring check device.

Further, as a recording medium which supplies a program, for example, it should be able to memorize the above-mentioned program such as a CD-ROM (Compact Disc Read Only Memory), a DVD-R (Digital Versatile Disk Recordable), an optical disc, a magnetic disk and a non-volatility memory card.

Although the part or everything of the above-mentioned exemplary embodiments can also be described like the following supplementary notes, they are not limited to the followings.

(Supplementary note 1) A wiring check device comprising: a wiring information acquisition unit which acquires wiring information on a wiring comprised in a printed wiring board having a multi-layered structure; a plane conductor detection unit which detects a plurality of plane conductors on multiple layers among the multi-layered structure comprising a layer located closest to a layer comprising the wiring; a plane conductor overlap configuration detection unit which detects a plane conductor overlap configuration of a configuration in which the plurality of plane conductors are overlapped; and a bridge point detection unit which detects a point where the wiring steps over a plane conductor excluded region in the plane conductor overlap configuration on the basis of a wiring-plane conductor overlap configuration of a configuration in which the wiring and the plane conductor overlap configuration are overlapped.

(Supplementary note 2) The wiring check device according to supplementary note 1, wherein a plane conductor provided in a layer of the same layer as the wiring is also included in the plurality of plane conductors which the plane conductor detection unit detects.

(Supplementary note 3) The wiring check device according to supplementary note 1 or 2, wherein the plane conductor overlap configuration detection unit detects an upper plane conductor overlap configuration of a configuration in which plane conductors disposed above the wiring are overlapped, and a lower plane conductor overlap configuration of a configuration in which plane conductors disposed below the wiring are overlapped, respectively.

(Supplementary note 4) The wiring check device according to any one of supplementary notes 1 to 3, wherein the plane conductor detection unit detects only a plane conductor which is disposed within a predetermined distance from the wiring in the laminating direction.

(Supplementary note 5) The wiring check device according to any one of supplementary notes 1 to 4, further comprising an area calculation unit which calculates an area of the plane conductor excluded region, wherein the bridge point to be detected by the bridge point detection unit is a point where the wiring steps over the plane conductor excluded region having an area equal to or more than a predetermined value.

(Supplementary note 6) The wiring check device according to any one of supplementary notes 1 to 5, further comprising: a boundary line intersection detection unit which detects a boundary line between a plane conductor formation region and a plane conductor excluded region in the respective layers of the multiple layers, and detects an intersection of the boundary line when the plurality of plane conductors are overlapped; and a joint detection unit which detects presence or absence of a joint between the plurality of plane conductors within a predetermined distance from the intersection of the boundary line.

(Supplementary note 7) The wiring check device according to supplementary note 6, wherein the joint detection unit detects presence or absence of the joint within a predetermined distance from a line segment where the boundary line on a layer nearest to a layer having the wiring and a plane conductor in a layer other than the layer nearest to the layer having the wiring overlap.

(Supplementary note 8) The wiring check device according to any one of supplementary notes 1 to 7, wherein the bridge point comprises an in-plane conductor bridge point which is a point where the wiring steps over a plane conductor excluded region formed inside the plane conductor, and an inter-plane conductor bridge point which is a point where the wiring steps over a plane conductor excluded region formed between a plurality of plane conductors, and the bridge point detection unit distinguishes and detects the in-plane conductor bridge point and the inter-plane conductor bridge point.

(Supplementary note 9) A wiring check system comprising: a wiring information acquisition means which acquires wiring information on a wiring comprised in a printed wiring board having a multi-layered structure; a plane conductor detection means which detects a plurality of plane conductors on multiple layers among the multi-layered structure which comprise a layer located closest to a layer comprising the wiring; a plane conductor overlap configuration detection means which detects a plane conductor overlap configuration of a configuration in which the plurality of plane conductors are overlapped; and a bridge point detection means which detects a point where the wiring steps over a plane conductor excluded region in the plane conductor overlap configuration on the basis of a wiring-plane conductor overlap configuration of a configuration in which the wiring and the plane conductor overlap configuration are overlapped.

(Supplementary note 10) The wiring check system according to supplementary note 9, wherein a plane conductor provided in a layer of the same layer as the wiring is also comprised in the plurality of plane conductors which the plane conductor detection means detects.

(Supplementary note 11) The wiring check system according to supplementary note 9 or 10, wherein the plane conductor overlap configuration detection means detects an upper plane conductor overlap configuration of a configuration in which plane conductors disposed above the wiring are overlapped, and a lower plane conductor overlap configuration of a configuration in which plane conductors disposed below the wiring are overlapped, respectively.

(Supplementary note 12) The wiring check system according to any one of supplementary notes 9 to 11, wherein the plane conductor detection means detects only a plane conductor which is disposed within a predetermined distance from the wiring in the laminating direction.

(Supplementary note 13) The wiring check system according to any one of supplementary notes 9 to 12, further comprising an area calculation means which calculates an area of the plane conductor excluded region, wherein the bridge point to be detected by the bridge point detection means is a point where the wiring steps over the plane conductor excluded region having an area equal to or more than a predetermined value.

(Supplementary note 14) The wiring check system according to any one of supplementary notes 9 to 13, further comprising: a boundary line intersection detection means which detects a boundary line between a plane conductor formation region and a plane conductor excluded region in the respective layers of the multiple layers, and detects an intersection of the boundary line when the plurality of plane conductors are overlapped; and a joint detection means which detects presence or absence of a joint between the plurality of plane conductors within a predetermined distance from the intersection of the boundary line.

(Supplementary note 15) The wiring check system according to supplementary note 14, wherein the joint detection means detects presence or absence of the joint within a predetermined distance from a line segment where the boundary line on a layer nearest to a layer having the wiring and a plane conductor in a layer other than the layer nearest to the layer having the wiring overlap.

(Supplementary note 16) The wiring check system according to any one of supplementary notes 9 to 15, wherein the bridge point comprises an in-plane conductor bridge point which is a point where the wiring steps over a plane conductor excluded region formed inside the plane conductor, and an inter-plane conductor bridge point which is a point where the wiring steps over a plane conductor excluded region formed between a plurality of plane conductors, and the bridge point detection means distinguishes and detects the in-plane conductor bridge point and the inter-plane conductor bridge point.

(Supplementary note 17) a wiring check system described in any one of supplementary notes 9 to 16, further comprising an output means which outputs information which the bridge point detection means detected.

(Supplementary note 18) A wiring checking method comprising: a wiring information acquisition step which acquires wiring information on a wiring comprised in a printed wiring board having a multi-layered structure; a plane conductor detection step which detects a plurality of plane conductors on multiple layers among the multi-layered structure comprising a layer located closest to a layer comprising the wiring; a plane conductor overlap configuration detection step which detects a plane conductor overlap configuration of a configuration in which the plurality of plane conductors are overlapped; and a bridge point detection step which detects a point where the wiring steps over a plane conductor excluded region in the plane conductor overlap configuration on the basis of a wiring-plane conductor overlap configuration of a configuration in which the wiring and the plane conductor overlap configuration are overlapped.

(Supplementary note 19) The wiring checking method according to supplementary note 18, wherein the plurality of plane conductors detected in the plane conductor detection step comprise a plane conductor which a layer of the same layer as the wiring has.

(Supplementary note 20) The wiring checking method according to supplementary note 18 or 19, wherein an upper plane conductor overlap configuration of a configuration in which plane conductors disposed above the wiring are overlapped, and a lower plane conductor overlap configuration of a configuration in which plane conductors disposed below the wiring are overlapped are detected respectively in the plane conductor overlap configuration detection step.

(Supplementary note 21) The wiring checking method according to any one of supplementary notes 18 to 20, wherein only a plane conductor which is disposed within a predetermined distance from the wiring in the laminating direction is detected in the plane conductor detection step.

(Supplementary note 22) The wiring checking method according to any one of supplementary notes 18 to 21, further comprising an area calculating step which calculates an area of the plane conductor excluded region, wherein the bridge point to be detected in the bridge point detection step is a point where the wiring steps over the plane conductor excluded region having an area equal to or more than a predetermined value.

(Supplementary note 23) The wiring checking method according to any one of supplementary notes 18 to 22, further comprising: a boundary line intersection detection step which detects a boundary line between a plane conductor formation region and a plane conductor excluded region in the respective layers of the multiple layers, and detects an intersection of the boundary line when the plurality of plane conductors are overlapped; and a joint detection step which detects presence or absence of a joint between the plurality of plane conductors within a predetermined distance from the intersection of the boundary line.

(Supplementary note 24) The wiring checking method according to supplementary note 23, wherein the joint detection step detects presence or absence of the joint within a predetermined distance from a line segment where the boundary line on a layer nearest to a layer having the wiring and a plane conductor in a layer other than the layer nearest to the layer having the wiring overlap.

(Supplementary note 25) The wiring checking method according to any one of supplementary notes 18 to 24, wherein the bridge point comprises an in-plane conductor bridge point which is a point where the wiring steps over a plane conductor excluded region formed inside the plane conductor, and an inter-plane conductor bridge point which is a point where the wiring steps over a plane conductor excluded region formed between a plurality of plane conductors, and the in-plane conductor bridge point and the inter-plane conductor bridge point are distinguished and detected in the bridge point detection step.

(Supplementary note 26) The wiring checking method according to any one of supplementary notes 18 to 25, further comprising an output step of outputting information which the bridge point detection step detected.

(Supplementary note 27) A wiring check program for making a computer executes steps of: a wiring information acquisition step which acquires wiring information on a wiring comprised in a printed wiring board having a multi-layered structure; a plane conductor detection step which detects a plurality of plane conductors on multiple layers among the multi-layered structure comprising a layer located closest to a layer comprising the wiring; a plane conductor overlap configuration detection step which detects a plane conductor overlap configuration of a configuration in which the plurality of plane conductors are overlapped; and a bridge point detection step which detects a point where the wiring steps over a plane conductor excluded region in the plane conductor overlap configuration on the basis of a wiring-plane conductor overlap configuration of a configuration in which the wiring and the plane conductor overlap configuration are overlapped.

(Supplementary note 28) A recording medium which is a computer readable storage medium records a wiring check program according to supplementary note 27.

Although the present invention has been described with reference to the exemplary embodiments as mentioned above, the present invention is not limited to the above-mentioned exemplary embodiments. Various change in the configurations and details of the invention of the present application which a person skilled in the art can understand within the scope of the invention of the present application can be made.

This application is based upon and claims the benefit of priority from Japanese Patent Application No. 2011-116002 filed on May 24, 2011, the disclosure of which is incorporated herein its entirety.

### INDUSTRIAL APPLICABILITY

The check system of a plane bridge wiring of a printed wiring board of the present invention is applicable in the use such as the wiring check tools of a printed wiring board for improving an electromagnetic noise characteristic.

### DESCRIPTION OF THE CODES

10, 20, 30, 40, 110, 240, 330 printed wiring board
11, 12, 21, 31, 32, 41, 50-52, 115, 116, 248-253, 277-282, 315, 316, 336-342, 415-417 plane conductor
13, 114, 254, 283, 284, 317-319, 335, 418-420 wiring
14 pad
15 SMA connector
100, 200, 300, 400 wiring check system
101 wiring information acquisition means
102 plane conductor detection means
103 plane conductor overlap configuration detection means
104 bridge point detection means
111-113, 241-247, 271-276, 311-314, 331-334, 411-414 Layer
117, 255, 295, 320, 321, 422, 423 plane conductor overlap configuration
118, 256, 322, 424 wiring-plane conductor overlap configuration
119 plane conductor non-forming region
120, 121, 257, 258, 289, 290, 293, 294, 323, 324 bridge point
210 recording device
211 design information recording unit
220 wiring check device
221 wiring information acquisition unit
222 plane conductor detection unit
223 plane conductor overlap configuration detection unit
224 bridge point detection unit
230 output device
259, 285 upper plane conductor overlap configuration
260, 286 lower plane conductor overlap configuration
287, 291 wiring-upper plane conductor overlap configuration
288, 292 wiring-lower plane conductor overlap configuration
297 input device
301 area calculation unit
302 hole filling unit
401 boundary line intersection detection unit
402 joint detection unit
421 boundary line intersection

What is claimed is:

1. A wiring check device comprising:
a wiring information acquisition unit acquiring wiring information on a wiring comprised in a printed wiring board having a multi-layered structure;
a plane conductor detection unit detecting a plurality of plane conductors on multiple layers among the multi-layered structure comprising a layer located closest to a layer comprising the wiring;
a plane conductor overlap configuration detection unit detecting a plane conductor overlap configuration of a configuration in which the plurality of plane conductors are overlapped; and
a bridge point detection unit detecting a point where the wiring steps over a plane conductor excluded region in the plane conductor overlap configuration on the basis of a wiring-plane conductor overlap configuration of a configuration in which the wiring and the plane conductor overlap configuration are overlapped.

2. The wiring check device according to claim 1, wherein the plane conductor overlap configuration detection unit detects an upper plane conductor overlap configuration of a configuration in which plane conductors disposed above the wiring are overlapped, and a lower plane conductor overlap configuration of a configuration in which plane conductors disposed below the wiring are overlapped, respectively.

3. The wiring check device according to claim 1, wherein the plane conductor detection unit detects only a plane conductor which is disposed within a predetermined distance from the wiring in the laminating direction.

4. The wiring check device according to claim 1, further comprising an area calculation unit calculating an area of the plane conductor excluded region,
wherein the bridge point which the bridge point detection unit detects is a point where the wiring steps over the plane conductor excluded region having an area equal to or more than a predetermined value.

5. The wiring check device according to claim 1, further comprising:
a boundary line intersection detection unit detecting a boundary line between a plane conductor formation region and a plane conductor excluded region in the respective layers of the multiple layers, and detects an intersection of the boundary line when the plurality of plane conductors are overlapped; and
a joint detection unit detecting presence or absence of a joint between the plurality of plane conductors within a predetermined distance from the intersection of the boundary line.

6. The wiring check device according to claim 5, wherein the joint detection unit detects presence or absence of the joint within a predetermined distance from a line segment where the boundary line on a layer nearest to a layer having the wiring and a plane conductor in a layer other than the layer nearest to the layer having the wiring.

7. (canceled)

8. (canceled)

9. (canceled)

10. (canceled)

11. The wiring check device according to claim 1, wherein the bridge point comprises an in-plane conductor bridge point which is a point where the wiring steps over a plane conductor excluded region formed inside the plane conductor, and an inter-plane conductor bridge point which is a point where the wiring steps over a plane conductor excluded region formed between a plurality of plane conductors, and the bridge point detection unit distinguishes and detects the in-plane conductor bridge point and the inter-plane conductor bridge point.

12. A wiring checking method comprising:
a wiring information acquisition step for acquiring wiring information on a wiring comprised in a printed wiring board having a multi-layered structure;
a plane conductor detection step for detecting a plurality of plane conductors on multiple layers among the multi-layered structure comprising a layer located closest to a layer comprising the wiring;
a plane conductor overlap configuration detection step for detecting a plane conductor overlap configuration of a configuration in which the plurality of plane conductors are overlapped; and
a bridge point detection step for detecting a point where the wiring steps over a plane conductor excluded region in the plane conductor overlap configuration on the basis of a wiring-plane conductor overlap configuration of a configuration in which the wiring and the plane conductor overlap configuration are overlapped.

13. The wiring checking method according to claim 12, wherein the plurality of plane conductors detected in the plane conductor detection step comprise a plane conductor which a layer of the same layer as the wiring has.

14. The wiring checking method according to claim 12, wherein an upper plane conductor overlap configuration of a configuration in which plane conductors disposed above the wiring are overlapped, and a lower plane conductor overlap configuration of a configuration in which plane conductors disposed below the wiring are overlapped are detected respectively in the plane conductor overlap configuration detection step.

15. The wiring checking method according to claim 12, wherein only a plane conductor which is disposed within a predetermined distance from the wiring in the laminating direction is detected in the plane conductor detection step.

16. The wiring checking method according to claim 12, further comprising an area calculating step for calculating an area of the plane conductor excluded region, wherein the bridge point to be detected in the bridge point detection step is a point where the wiring steps over the plane conductor excluded region having an area equal to or more than a predetermined value.

17. The wiring checking method according to claim 12, further comprising:
a boundary line intersection detection step for detecting a boundary line between a plane conductor formation region and a plane conductor excluded region in the respective layers of the multiple layers, and detects an intersection of the boundary line when the plurality of plane conductors are overlapped; and
a joint detection step for detecting presence or absence of a joint between the plurality of plane conductors within a predetermined distance from the intersection of the boundary line.

18. The wiring checking method according to claim 17, wherein the joint detection step detects presence or absence of the joint within a predetermined distance from a line segment where the boundary line on a layer nearest to a layer having the wiring and a plane conductor in a layer other than the layer nearest to the layer having the wiring overlap.

19. The wiring checking method according to claim 12, wherein the bridge point comprises an in-plane conductor bridge point which is a point where the wiring steps over a plane conductor excluded region formed inside the plane conductor, and an inter-plane conductor bridge point which is a point where the wiring steps over a plane conductor excluded region formed between a plurality of plane conductors, and the in-plane conductor bridge point and the inter-plane conductor bridge point are distinguished and detected in the bridge point detection step.

20. The wiring checking method according to claim 12, further comprising an output step of outputting information which the bridge point detection step detected.

21. A computer readable storage medium for recording a wiring check program, the wiring check program making a computer executes steps of:
a wiring information acquisition step for acquiring wiring information on a wiring comprised in a printed wiring board having a multi-layered structure;
a plane conductor detection step for detecting a plurality of plane conductors on multiple layers among the multi-layered structure comprising a layer located closest to a layer comprising the wiring;
a plane conductor overlap configuration detection step for detecting a plane conductor overlap configuration of a configuration in which the plurality of plane conductors are overlapped; and
a bridge point detection step for detecting a point where the wiring steps over a plane conductor excluded region in the plane conductor overlap configuration on the basis of a wiring-plane conductor overlap configuration of a configuration in which the wiring and the plane conductor overlap configuration are overlapped.
